(19) United States
(12) Patent Application Publication
(10) Pub. No.: US 2023/0200077 A1
(43) Pub. Date: Jun. 22, 2023

(54) SEMICONDUCTOR DEVICE AND AN ELECTRONIC SYSTEM INCLUDING THE SEMICONDUCTOR DEVICE

(71) Applicant: SAMSUNG ELECTRONICS CO., LTD., Suwon-is (KR)

(72) Inventors: Hyunjung LEE, Suwon-is (KR); Jaeho CHOI, Seoul (KR); Hanmei CHOI, Seoul (KR)

(21) Appl. No.: 18/080,013

(22) Filed: Dec. 13, 2022

(30) Foreign Application Priority Data
Dec. 16, 2021 (KR) 10-2021-0181033

(51) Int. Cl. H10B 43/40; H10B 41/27; H10B 41/41; H10B 43/27

(52) U.S. Cl. CPC H01L 27/11573; H01L 27/11529; H01L 27/11556; H01L 27/11582

(57) ABSTRACT

A semiconductor device includes: a periphery circuit structure on a substrate; and a memory cell array on the periphery circuit structure, and including memory cells arranged in a first direction substantially perpendicular to an upper surface of the substrate, wherein the periphery circuit structure includes: a first element separation layer on the substrate and defining a first active region; a channel semiconductor layer on the first active region and at a higher level than an upper surface of the first element separation layer; a first gate structure on the channel semiconductor layer; a second element separation layer on the substrate, defining a second active region and a third active region, and including an upper surface at a higher level than the upper surface of the first element separation layer; a second gate structure on the second active region; and a third gate structure on the third active region.

### CROSS REFERENCE TO RELATED APPLICATION

This application claims priority under 35 U.S.C. §119 to Korean Patent Application No. 10-2021-0181033, filed on Dec. 16, 2021 in the Korean Intellectual Property Office, the disclosure of which is incorporated by reference herein in its entirety.

### Technical Field

The inventive concept relates to a semiconductor device and an electronic system including the semiconductor device, and more particularly, to a semiconductor device having a vertical channel and an electronic system including the semiconductor device.

### Discussion of Related Art

In today’s electronic systems, copious amounts of data are being managed, and consequently, a semiconductor device capable of storing large volumes of data is required. One of methods to that have been developed to increase the data storage capacity of a semiconductor device, involves arranging memory cell three-dimensionally instead of two-dimensionally.

### SUMMARY

The inventive concept provides a semiconductor device, in which a periphery (or peripheral) circuit transistor has an optimized performance, and a manufacturing method of the semiconductor device.

The inventive concept provides an electronic system including the semiconductor device.

According to an embodiment of the inventive concept, there is provided a semiconductor device including: a periphery circuit structure arranged on a substrate; and a memory cell array arranged on the periphery circuit structure, and including a plurality of memory cells arranged in a first direction substantially perpendicular to an upper surface of the substrate, wherein the periphery circuit structure includes: a first element separation layer arranged on the substrate and defining a first active region; a channel semiconductor layer arranged on the first active region and at a higher level than an upper surface of the first element separation layer; a first gate structure arranged on the channel semiconductor layer; a second element separation layer arranged on the substrate, defining a second active region and a third active region, and including an upper surface at a higher level than the upper surface of the first element separation layer; a second gate structure arranged on the second active region; and a third gate structure arranged on the third active region.

According to an embodiment of the inventive concept, there is provided a semiconductor device including: a first element separation layer arranged on a substrate and defining a first active region; a second element separation layer arranged on the substrate, defining a second active region and a third active region, and including an upper surface at a higher level than an upper surface of the first element separation layer; a first transistor arranged on the substrate and having a first threshold voltage, the first transistor including: the first active region; a channel semiconductor layer arranged on the first active layer and at a higher level than the upper surface of the first element separation layer; and a first gate structure arranged on the channel semiconductor layer; a second transistor arranged on the substrate and having a second threshold voltage, the second transistor including: the second active region; and a second gate structure arranged on the second active region; and a third transistor arranged on the substrate and having a third threshold voltage, the third transistor including: the third active region; and a third gate structure arranged on the third active region.

According to an embodiment of the inventive concept, there is provided an electronic system including: a first substrate; a semiconductor device on the first substrate; and a controller electrically connected to the semiconductor device, wherein the semiconductor device includes: a periphery circuit structure arranged on a second substrate; and a memory cell array arranged on the periphery circuit structure, and including a plurality of memory cells arranged in a first direction substantially perpendicular to an upper surface of the second substrate, wherein the peripheral circuit structure includes: a first element separation layer arranged on the second substrate and defining a first active region; and a second element separation layer arranged on the second substrate, defining a second active region and a third active region, and including an upper surface at a higher level than an upper surface of the first element separation layer, a first transistor arranged on the second substrate and having a first threshold voltage, the first transistor including: the first active region; a channel semiconductor layer arranged on the first active region and at a higher level than the upper surface of the first element separation layer, and including silicon germanium; and a first gate structure arranged on the channel semiconductor layer, a second transistor arranged on the second substrate and having a second threshold voltage, the second transistor including: the second active region; and a second gate structure arranged on the second active region; and a third transistor arranged on the second substrate and having a third threshold voltage, the third transistor including: the third active region; and a third gate structure arranged on the third active region.

### BRIEF DESCRIPTION OF THE DRAWINGS

Embodiments of the inventive concept will be more clearly understood from the following detailed description taken in conjunction with the accompanying drawings in which:

FIG. 1 is a block diagram of a semiconductor device according to an example embodiment of the inventive concept;

FIG. 2 illustrates an equivalent circuit diagram of a memory cell array of a semiconductor device, according to an example embodiment of the inventive concept;

FIG. 3 is a perspective view illustrating a representative configuration of a semiconductor device, according to an example embodiment of the inventive concept;

FIG. 4 is a cross-sectional view of the semiconductor device of FIG. 3,

FIG. 5 is a layout diagram of a periphery circuit structure in FIG. 3;

FIG. 6 is a cross-sectional view taken along line A1-A1′ in FIG. 5;

FIG. 7 is an enlarged view of region CX1 in FIG. 4;

FIG. 8 is an enlarged view of region CX2 in FIG. 4;

FIG. 9 is a cross-sectional view of a semiconductor device according to an example embodiment of the inventive concept;

FIG. 10 is a cross-sectional view of a semiconductor device according to an example embodiment of the inventive concept;

FIGS. 11, 12, 13, 14, 15, 16, 17, 18, 19, 20, 21, 22, 23, 24 and 25 are cross-sectional views illustrating a manufacturing method of a semiconductor device, according to example embodiments of the inventive concept;

FIG. 26 is a schematic diagram of a data storage system including a semiconductor device, according to an example embodiment of the inventive concept,

FIG. 27 is a perspective view of a data storage system including a semiconductor device, according to an example embodiment of the inventive concept, and

FIG. 28 is a schematic cross-sectional view of a semiconductor package according to an example embodiment of the inventive concept.

### DETAILED DESCRIPTION OF THE EMBODIMENTS

Hereinafter, embodiments of the inventive concept are described in detail in conjunction with the accompanying drawings.

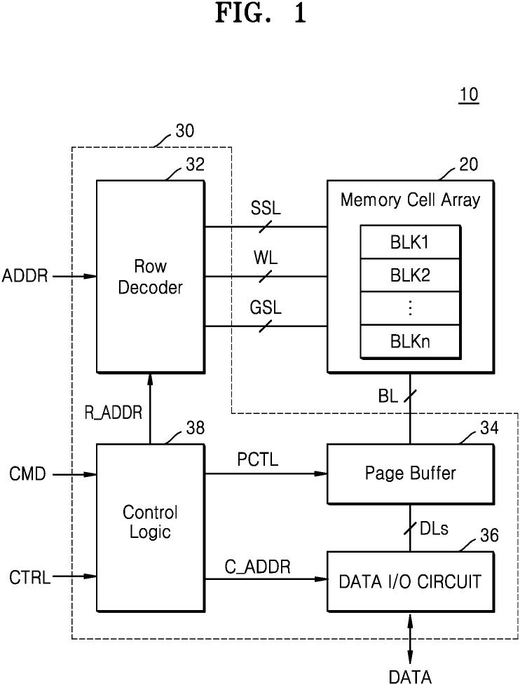

FIG. 1 is a block diagram of a semiconductor device 10 according to an example embodiment of the inventive concept.

Referring to FIG. 1, the semiconductor device 10 may include a memory cell array 20 and a periphery circuit 30. The memory cell array 20 may include a plurality of memory cell blocks BLK1, BLK2, ..., BLKn. Each of the plurality of memory cell blocks BLK1, BLK2, ..., BLKn may include a plurality of memory cells. The plurality of memory cell blocks BLK1, BLK2, ..., BLKn may be connected to the periphery circuit 30 via a bit line BL, a word line WL, a string selection line SSL, and a ground selection line GSL.

The periphery circuit 30 may include a row decoder 32, a page buffer 34, a data input/output (I/O) circuit 36, and a control logic 38. The periphery circuit 30 may further include an I/O interface, a column logic, a voltage generator, a pre-decoder, a temperature sensor, a command decoder, an address decoder, an amplification circuit, etc.

The memory cell array 20 may be connected to the page buffer 34 via the bit line BL, and may be connected to the row decoder 32 via the word line WL, the string selection line SSL, and the ground selection line GSL. In the memory cell array 20, each of the plurality of memory cells included in the plurality of memory cell blocks BLK1, BLK2, ..., BLKn may include a flash memory cell. The memory cell array 20 may include a three-dimensional memory cell array. The three-dimensional memory cell array may include a plurality of NAND strings, and each NAND string may include a plurality of memory cells connected to a plurality of word lines WL, which are vertically stacked on a substrate.

The periphery circuit 30 may receive an address ADDR, a command CMD, and a control signal CTRL, from a device outside of the semiconductor device 10, and may transceive data DATA to/from a device outside the semiconductor device 10.

The row decoder 32 may select at least one of the plurality of memory cell blocks BLK1, BLK2, ..., BLKn in response to the address ADDR provided from the outside of the semiconductor device 10, and may select the word line WL, the string selection line SSL, and the ground selection line GSL of the selected at least one memory cell block. The row decoder 32 may transmit a voltage for performing a memory operation to the word line WL of the selected at least one memory cell block. The memory operation may include a read, program or erase operation.

The page buffer 34 may be connected to the memory cell array 20 via the bit line BL. The page buffer 34 may act as a write driver during a program operation, and apply, to the bit line BL, a voltage according to data DATA to be stored in the memory cell array 20. In addition, the page buffer 34 may operate as a sensing amplifier during a read operation to detect the data DATA stored in the memory cell array 20. The page buffer 34 may operate according to a control signal PCTL provided by the control logic 38.

The data I/O circuit 36 may be connected to the page buffer 34 via data lines DL. The data I/O circuit 36 may receive the data DATA from a memory controller during the program operation, and provide program data DATA to the page buffer 34 based on a column address C_ADDR provided by the control logic 38. The data I/O circuit 36 may provide the memory controller with read the data DATA stored in the page buffer 34 based on the column address C ADDR provided by the control logic 38 during the read operation.

The data I/O circuit 36 may transmit an address or a command to be input, to the control logic 38 or the row decoder 32. The periphery circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32, and provide the column address C_ADDR to the data I/O circuit 36. The control logic 38 may generate various internal control signals to be used by the semiconductor device 10 in response to the control signal CTRL. For example, the control logic 38 may control voltage levels to be provided to the word line WL and the bit line BL, when memory operations such as the program operation and an erase operation are performed

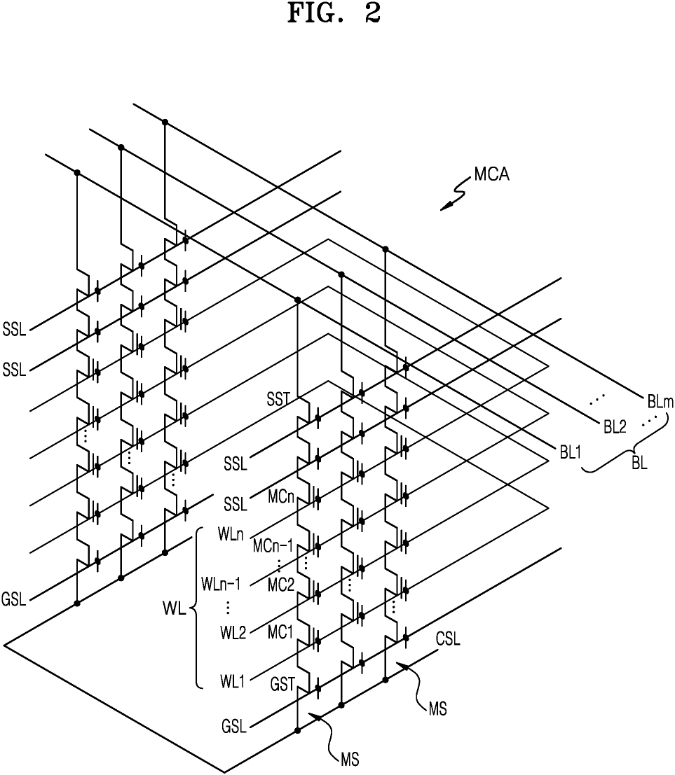

FIG. 2 illustrates an equivalent circuit diagram of a memory cell array MCA of the semiconductor device 10, according to an example embodiment of the inventive concept,

Referring to FIG. 2, the memory cell array MCA may include a plurality of memory cell strings MS. The memory cell array MCA may include a plurality of bit lines BL (including BL1, BL2, ..., BLm), a plurality of word lines WL, (including WL1, WL2, ..., WLn-1, WLn), at least one string selection line SSL, at least one ground selection line GSL, and a common source line CSL. A plurality of memory cell strings MS may be formed between the plurality of bit lines BL (including BL1, BL2, ..., BLm) and the common source line CSL. In the example of FIG. 2, each of the plurality of memory cell strings MS includes two string selection lines SSL, but the inventive concept is not limited thereto. For example, each of the plurality of memory cell strings MS may also include one string selection line SSL.

Each of the plurality of memory cell strings MS may include a string selection transistor SST, a ground selection transistor GST, and a plurality of memory cell transistors MC1, MC2, ..., MCn-1, MCn. A drain region of the string selection transistor SST may be connected to the plurality of bit lines BL (including BL1, BL2, ..., BLm), and a source region of the ground selection transistor GST may be connected to the common source line CSL. The common source line CSL may include a region, to which the source regions of a plurality of ground select transistors GST are connected in common.

The string selection transistor SST may be connected to the string selection line SSL, and the ground selection transistor GST may be connected to the ground selection line GSL. The plurality of memory cell transistors MC1, MC2, ..., MCn-1, MCn may be connected to the plurality of word lines WL (including WL1, WL2, ..., WLn-1, and WLn), respectively.

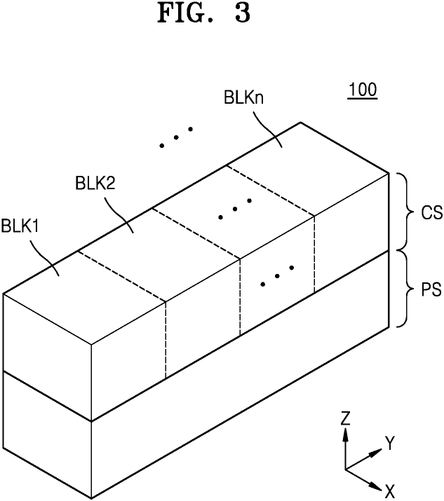

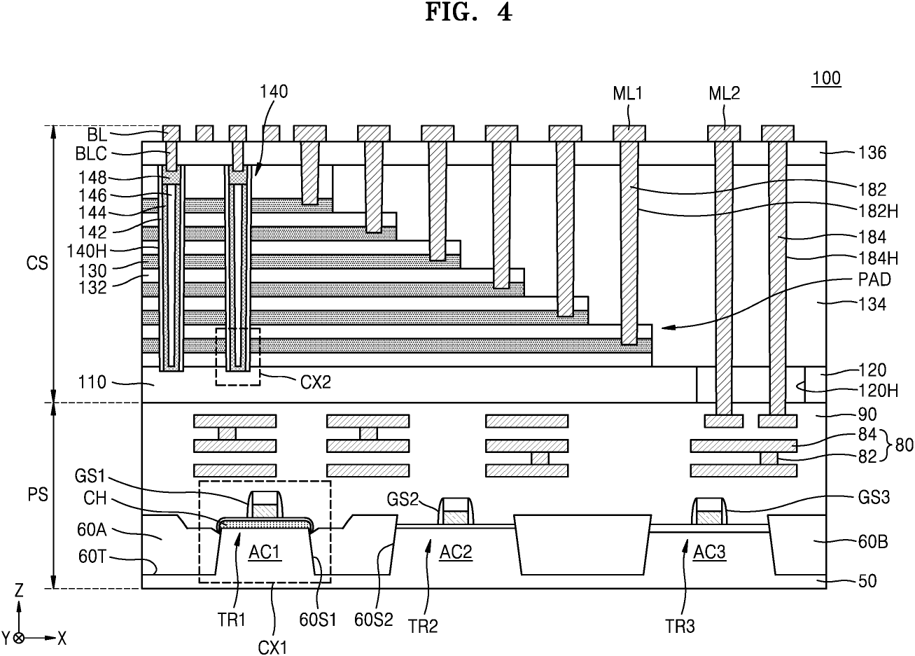

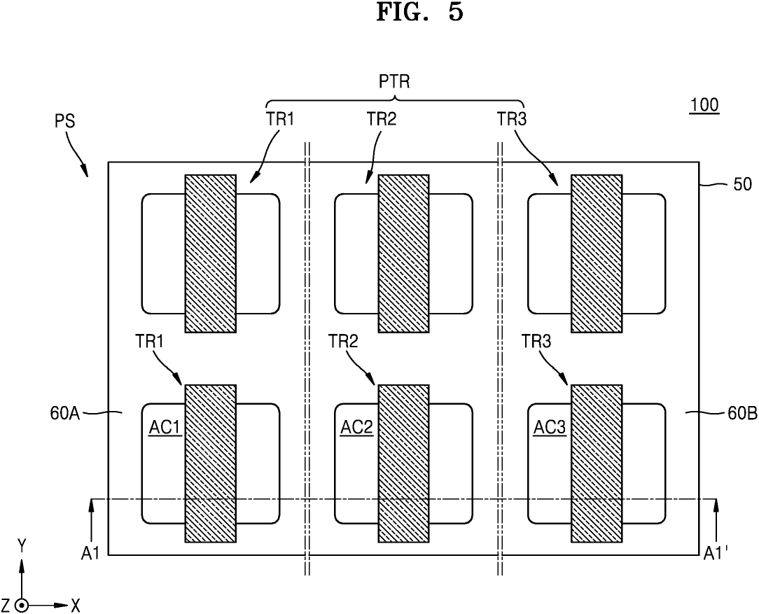

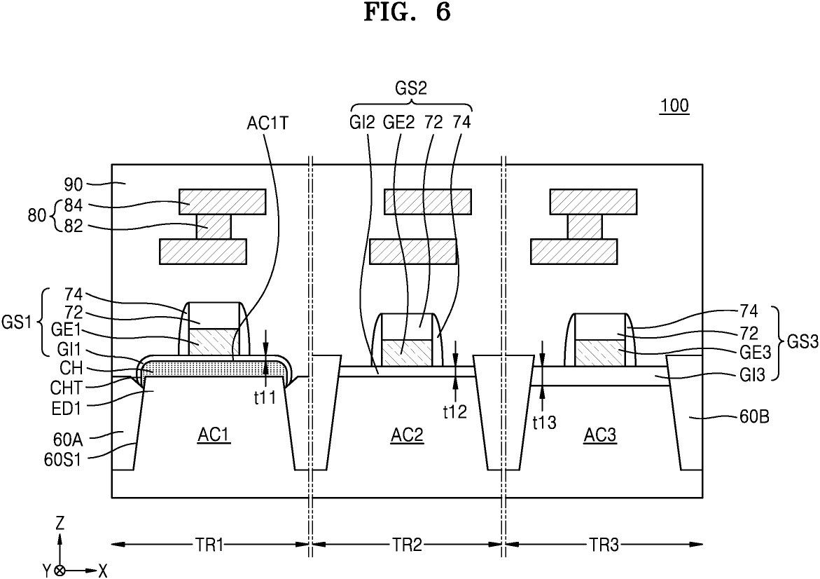

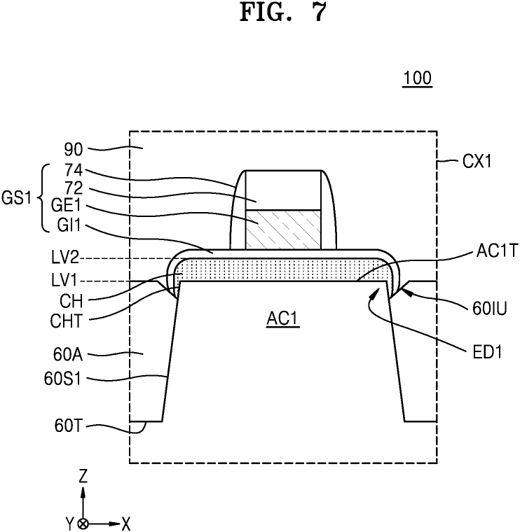

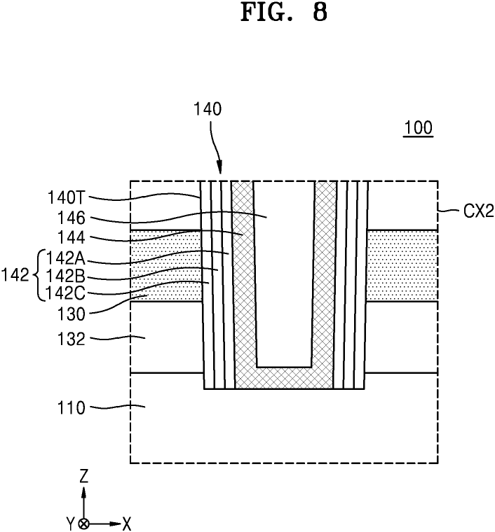

FIGS. 3 through 8 are diagrams for explaining a semiconductor device 100 according to example embodiments of the inventive concept. FIG. 3 is a perspective view illustrating a representative configuration of the semiconductor device 100, according to an example embodiment of the inventive concept. FIG. 4 is a cross-sectional view of the semiconductor device 100 of FIG. 3. FIG. 5 is a layout diagram of a periphery circuit structure PS in FIG. 3, FIG. 6 is a cross-sectional view taken along line A1-A1′ in FIG. 5, FIG. 7 is an enlarged view of region CX1 in FIG. 4, and FIG. 8 is an enlarged view of region CX2 in FIG. 4.

Referring to FIGS. 3 through 8, the semiconductor device 100 may include a cell array structure CS and a periphery circuit structure PS, which overlap each other in a vertical direction (Z direction). The cell array structure CS may include the memory cell array 20 described with reference to FIG. 1, and the periphery circuit structure PS may include the periphery circuit 30 described with reference to FIG. 1.

The cell array structure CS may include the plurality of memory cell blocks BLK1, BLK2, ..., BLKn. Each of the plurality of memory cell blocks BLK1, BLK2, ..., BLKn may include memory cells, which are three-dimensionally arranged.

The periphery circuit structure PS may include a periphery circuit transistor PTR and a periphery circuit wiring structure 80, which are arranged on and over a substrate 50, respectively. On the substrate 50, active regions AC1, AC2, and AC3 may be defined by element separation layers 60A and 60B, and the periphery circuit transistor PTR may be formed on the active regions AC1, AC2, and AC3.

The substrate 50 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon-germanium. The substrate 50 may be provided as a bulk wafer or an epitaxial layer. In another embodiment of the inventive concept, the substrate 50 may include a silicon-on-insulator (SOI) substrate or a germanium-on-insulator (GeOI) substrate.

The periphery circuit transistor PTR may include a first transistor TR1, a second transistor TR2, and a third transistor TR3. For example, the first transistor TR1 may include a transistor having a first threshold voltage, the second transistor TR2 may include a transistor including a second threshold voltage greater than the first threshold voltage, and the third transistor TR3 may include a transistor having a third threshold voltage greater than the first and second threshold voltages. In another embodiment, at least two of the first to third transistors TR1-TR3 may have the same threshold voltage.

In example embodiments of the inventive concept, the third transistor TR3 may include a transistor arranged in a high voltage region of the periphery circuit structure PS, the second transistor TR2 may include a transistor arranged in a mid-voltage region of the periphery circuit structure PS, and the first transistor TR1 may include a transistor arranged in a low voltage region of the periphery circuit structure PS.

In some embodiments of the inventive concept, the first transistor TR1 may include a p-channel metal-oxide-semiconductor (PMOS) transistor, the second transistor TR2 may include a PMOS transistor or an n-channel metal-oxide-semiconductor (NMOS) transistor, and the third transistor TR3 may include a PMOS transistor or an NMOS transistor. In other embodiments of the inventive concept, the first transistor TR1 may include an NMOS transistor, the second transistor TR2 may include a PMOS transistor or an NMOS transistor, and the third transistor TR3 may include a PMOS transistor or an NMOS transistor.

On the substrate 50, a first element separation layer 60A and a second element separation layer 60B may be arranged in an element separation trench 60T. For example, an upper level LV1 of the first element separation layer 60A may be lower than an upper surface level of the second element separation layer 60B. In example embodiments of the inventive concept, the first element separation layer 60A and the second element separation layer 60B may include silicon oxide, silicon nitride, silicon oxynitride, or a combination thereof.

The first element separation layer 60A may define a first active region AC1, and the second element separation layer 60B may define a second active region AC2 and a third active region AC3. The first transistor TR1 may be provided on the first active region AC1 defined by the first element separation layer 60A, the second transistor TR2 may be provided on the second active region AC2 defined by the second element separation layer 60B, and the third transistor TR3 may be provided on the third active region AC3 defined by the second element separation layer 60B.

The first transistor TR1 may include the first active region AC1, a channel semiconductor layer CH, and a first gate structure GS1.

The first element separation layer 60A may include a first side 60S1 contacting the first active region AC1 and a second side 60S2 opposite to the first side 60S1, and an upper surface of the first side 60S1 may be arranged at a lower level than an edge portion ED1 of the first active region AC1. For example, as illustrated in FIG. 7, the first element separation layer 60A may include an inclination upper surface 60IU arranged adjacent to the first side 60S1. Accordingly, the edge portion ED1 of the first active region AC1 may not be covered by the first element separation layer 60A. The inclination upper surface 60IU may be at its lowest point where it contact the edge portion ED1 of the first active region AC1 and at its highest point when it reaches the upper level LV1 of the first element separation layer 60A.

The channel semiconductor layer CH may be arranged at a certain thickness on an upper surface of the first active region AC1. An upper level LV2 of the channel semiconductor layer CH may be higher than the upper level LV1 of the first element separation layer 60A.

In example embodiments of the inventive concept, the channel semiconductor layer CH may cover an entire upper surface AC1T of the first active region AC1, and extend downwardly along the edge portion ED1. In other words, the channel semiconductor layer CH may overlap the edge portion ED1. A portion of the channel semiconductor layer CH, which is arranged on the edge portion ED1 and extends downwardly, may be referred to as a tail portion CHT. In FIG. 7, the tail portion CHT is illustrated as covering the edge portion ED1 of the first active region AC1 and extending downwardly so that an end portion of the tail portion CHT is arranged adjacent to and does contact the first element separation layer 60A, but in other embodiments of the inventive concept, unlike as illustrated in FIG. 7, the edge portion of the tail portion CHT may also be arranged to contact the first element separation layer 60A.

In example embodiments of the inventive concept, the channel semiconductor layer CH may include a different semiconductor material from the substrate 50. In some embodiments of the inventive concept, the substrate 50 may include silicon, and the channel semiconductor layer CH may include silicon germanium. In other embodiments of the inventive concept, the substrate 50 may include silicon, and the channel semiconductor layer CH may include germanium. In addition, in other embodiments of the inventive concept, the substrate 50 may include silicon germanium, and the channel semiconductor layer CH may include germanium.

In example embodiments of the inventive concept, the channel semiconductor layer CH may include a material layer formed on an upper surface of the substrate 50, in other words, the upper surface of the first active region AC1, by using an epitaxial growth process. For example, the channel semiconductor layer CH may include a material layer formed on the entire upper surface AC1T and the edge portion ED1 of the first active region AC1 by using an epitaxial growth process, in a state in which the entire upper surface AC1T and the edge portion ED1 of the first active region AC1 are not covered by the first element separation layer 60A. This may permit the channel semiconductor layer CH to be substantially free of crystal defects such as dislocation and stacking faults. Particularly, the crystal defect may not occur inside the tail portion CHT covering the edge portion ED1 of the first active region AC1. Accordingly, the channel semiconductor layer CH may have a good crystal quality.

The first gate structure GS1 may include a first gate insulating layer GI1, a first gate electrode GE1, a gate capping layer 72, and a gate spacer 74.

The first gate insulating layer GI1 may include at least one of a silicon oxide layer, a silicon nitride layer, a silicon oxynitride layer, an oxide/nitride/oxide (ONO) layer, and a high-k dielectric layer having a higher dielectric constant than the silicon oxide layer. The first gate insulating layer GI1 may cover the entire upper surface AC1T of the first active region AC1, cover the tail portion CHT of the channel semiconductor layer CH on the edge portion ED1 of the first active region AC1, and extend downwardly. The upper level LV1 of the first element separation layer 60A may be lower than an upper surface level of the first gate insulating layer GI1.

The first gate electrode GE1 may include doped polysilicon, ruthenium (Ru), titanium (Ti), tantalum (Ta), niobium (Nb), iridium (Ir), molybdenum (Mo), tungsten (W), titanium nitride (TiN), tantalum nitride (TaN), niobium nitride (NbN), molybdenum nitride (MoN), tungsten nitride (WN), titanium silicon nitride (TiSiN), or a combination thereof.

A source/drain region may be further arranged in the channel semiconductor layer CH on both sides of the first gate structure GS1. The source/drain region may include a region doped with impurities.

The gate capping layer 72 may be arranged on the first gate electrode GE1, and include silicon nitride. The gate spacer 74 may be arranged on sidewalls of the gate capping layer 72 and the first gate electrode GE1, and include silicon nitride. For example, the gate capping layer 72 and the gate spacer 74 may include the same material.

The second transistor TR2 may include the second active region AC2 and a second gate structure GS2, and the third transistor TR3 may include the third active region AC3 and a third gate structure GS3.

The second element separation layer 60B may define the second active region AC2 and the third active region AC3, and may include an upper surface arranged at a higher level than upper surfaces of the second active region AC2 and the third active region AC3. In addition, the second element separation layer 60B may include the upper surface arranged at a higher level than the first element separation layer 60A.

The second gate structure GS2 may include a second gate insulating layer GI2, a second gate electrode GE2, the gate capping layer 72, and the gate spacer 74, and the third gate structure GS3 may include a third gate insulating layer GI3, a third gate electrode GE3, the gate capping layer 72, and the gate spacer 74.

The second gate insulating layer GI2 and the third gate insulating layer GI3 may include at least one selected from a silicon oxide layer, a silicon nitride layer, a silicon oxynitride layer, an ONO layer, or a high-k layer having a higher dielectric constant than a silicon oxide layer.

As illustrated in FIG. 6, the second gate insulating layer GI2 may be arranged to cover an entire upper surface of the second active region AC2, and may contact sidewalls of the second element separation layer 60B. In addition, the third gate insulating layer GI3 may be arranged to cover an entire upper surface of the third active region AC3, and may contact the sidewalls of the second element separation layer 60B. The upper surface of the second element separation layer 60B may be arranged at a higher level than an upper surface of the second gate insulating layer GI2 and an upper surface of the third gate insulating layer GI3.

In example embodiments of the inventive concept, the first gate insulating layer GI1 may have a first thickness t11 in the vertical direction (Z direction), the second gate insulating layer GI2 may have a second thickness t12 greater than the first thickness t11 in the vertical direction (Z direction), and the third gate insulating layer GI3 may have a third thickness t13 greater than the second thickness t12 in the vertical direction (Z direction). As illustrated in FIG. 6, the upper surface of the second gate insulating layer GI2 and the upper surface of the third gate insulating layer G13 may be arranged at the same vertical level, and accordingly, the upper surface of the second active region AC2 may be arranged at a higher vertical level than the upper surface of the third active region AC3. In addition, a level difference between the second gate insulating layer GI2 and the second element separation layer 60B may be the same as or similar to a level difference between the third gate insulating layer GI3 and the second element separation layer 60B.

The second gate electrode GE2 and the third gate electrode GE3 may include doped polysilicon, Ru, Ti, Ta, Nb, Ir, Mo, W, TiN, TaN, NbN, MoN, WN, TiSiN, or a combination thereof.

A source/drain region may be further arranged in the second active region AC2 on both sides of the second gate structure GS2, and in the third active region AC3 on both sides of the third gate structure GS3. The source/drain region may include a region doped with impurities.

The periphery circuit wiring structure 80 may include a plurality of periphery circuit contacts 82 and a plurality of periphery circuit wiring layers 84. On the substrate 50, an interlayer insulating layer 90 covering the periphery circuit transistor PTR and the periphery circuit wiring structure 80 may be arranged. The plurality of periphery circuit wiring layers 84 may have a multilayer structure including a plurality of metal layers arranged at different vertical levels from each other.

A common source plate 110 may be arranged on the interlayer insulating layer 90. In example embodiments of the inventive concept, the common source plate 110 may function as a source region supplying a current to vertical-type memory cells formed in the cell array structure CS. In example embodiments of the inventive concept, the common source plate 110 may include at least one of, for example, Si, Ge, silicon germanium (SiGe), gallium arsenide (GaAs), indium gallium arsenide (InGaAs), aluminum gallium arsenide (AlGaAs), or a combination thereof. In addition, the common source plate 110 may include a semiconductor doped with n-type impurities. In addition, the common source plate 110 may have a crystal structure including at least one selected from a single crystal structure, an amorphous structure, and a polycrystalline structure. In some embodiments of the inventive concept, the common source plate 110 may include polysilicon doped with n-type impurities.

The common source plate 110 may include an opening 120H, and an insulation plug 120 may fill the inside of the opening 120H of the common source plate 110. The insulation plug 120 may include an upper surface arranged on the same level as an upper surface of the common source plate 110.

A plurality of gate electrodes 130 and a plurality of mold insulating layers 132 may be alternately arranged on the common source plate 110 in the vertical direction (Z direction).

The gate electrode 130 may include a metal such as W, nickel (Ni), cobalt (Co), and Ta, a metal silicide such as W silicide, Ni silicide, Co silicide, and Ta. silicide, and doped polysilicon, TiN, TaN, WN, or a combination thereof.

In example embodiments of the inventive concept, the plurality of gate electrodes 130 may correspond to the ground selection line GSL, the word line WL (including WL1, WL2,..., WLn-1, and WLn), and at least one string selection line SSL, which constitute the memory cell string MS (refer to FIG. 2). For example, the first gate electrode 130 at the lowermost portion may function as the ground selection line GSL, two gate electrodes 130 at the uppermost portion may function as the string selection line SSL, and the other gate electrodes 130 may function as the word line WL. Accordingly, the memory cell string MS, to which the ground selection transistor GST, the string selection transistor SST, and the memory cell transistors MC1, MC2,..., MCn-1, and MCn therebetween are connected in series, may be provided. In some embodiments of the inventive concept, at least one of the gate electrodes 130 may also function as a dummy word line, but the inventive concept is not limited thereto.

A plurality of channel structures 140 may penetrate the plurality of gate electrodes 130 and the plurality of mold insulating layers 132 from the upper surface of the common source plate 110, and may extend in the vertical direction (Z direction). Each of the plurality of channel structures 140 may include a gate insulating layer 142, a channel layer 144, a filled insulating layer 146, and a conductive plug 148, which are arranged inside a channel hole 140H. The gate insulating layer 142 and the channel layer 144 may be sequentially arranged on sidewalls of the channel hole 140H. For example, the gate insulating layer 142 may be conformally arranged on the sidewalls of the channel hole 140H, and the channel layer 144 may be conformally arranged on the sidewalls and a bottom portion of the channel hole 140H. The filled insulating layer 146 filling a remaining space of the channel hole 140H may be on the channel layer 144. The conductive plug 148 contacting the channel layer 144 and blocking an inlet of the channel hole 140H may be arranged on an upper side of the channel hole 140H.

In example embodiments of the inventive concept, the channel layer 144 may be arranged to contact the upper surface of the common source plate 110 on the bottom portion of the channel hole 140H. In some embodiments of the inventive concept, as illustrated in FIG. 4, a bottom surface of the channel layer 144 may be arranged at a lower level than the upper surface of the common source plate 110, but the inventive concept is not limited thereto.

As illustrated in FIG. 8, the gate insulating layer 142 may have a structure, which sequentially includes a tunneling dielectric layer 142A, a charge storage layer 142B, and a blocking dielectric layer 142C on an outer sidewall of the channel layer 144. Relative thicknesses of the tunneling dielectric layer 142A, the charge storage layer 142B, and the blocking dielectric layer 142C, which constitute the gate insulating layer 142, may not be limited to those illustrated in FIG. 7, but may be variously modified.

The tunneling dielectric layer 142A may include silicon oxide, hafnium oxide, aluminum oxide, zirconium oxide, tantalum oxide, etc. The charge storage layer 142B may include an area, in which electrons having penetrated the tunneling dielectric layer 142A from the channel layer 144 are stored, and may include silicon nitride, boron nitride, silicon boron nitride, or polysilicon doped with impurities. The blocking dielectric layer 142C may include silicon oxide, silicon nitride, or a metal oxide having a higher dielectric constant than silicon oxide. The metal oxide may include hafnium oxide, aluminum oxide, zirconium oxide, tantalum oxide, or a combination thereof.

The plurality of gate electrodes 130 may extend to have shorter length in a first horizontal direction (X) away from the upper surface of the common source plate 110, and a pad structure PAD may be referred to as portions of the gate electrodes 130 arranged in a stair shape. A cover insulating layer 134 may be arranged on the pad structure PAD, and an upper insulating layer 136 may be arranged on a mold insulating layer 132 at the uppermost portion and the cover insulating layer 134.

A cell contact plug 182 connected to the pad structure PAD may be arranged inside a cell contact hole 182H penetrating the cover insulating layer 134 and the upper insulating layer 136, and a conductive through via 184 may be arranged inside a through hole 184H penetrating the upper insulating layer 136 and the insulation plug 120. For example, the cell contact plug 182 and the conductive through via 184 may each include W, Ti, Ta, copper, aluminum, TiN, TaN, WN, or a combination thereof. The conductive through via 184 may be configured to be connected to the periphery circuit transistor PTR via the periphery circuit wiring layer 84.

A bit line contact BLC may penetrate the upper insulating layer 136 and be connected to the channel structure 140, and the bit line BL connected to the bit line contact BLC may be arranged on the upper insulating layer 136. In addition, a first wiring line ML1 connected to the cell contact plug 182 and a second wiring line ML2 connected to the conductive through via 184 may be arranged on the upper insulating layer 136.

In general, the periphery circuit structure PS may include various periphery circuit transistors PTR providing power and signals for driving the cell array structure CS to the cell array structure CS. Particularly, because it is necessary to form a relatively thick gate insulating layer for forming a transistor included in a high voltage region (for example, a transistor such as the third transistor TR3), an upper surface of an element separation layer may be formed at a higher level than an upper surface of a gate insulating layer to prevent a thickness reduction of the gate insulating layer. However, in a process of forming a channel semiconductor layer for a transistor included in a low voltage region, there may be a growth limit due to an interface of the high element separation layer, and thus, a crystal defect at an edge portion of an active region may occur.

However, according to example embodiments of the inventive concept described above, a recess process may be performed so that the first element separation layer 60A arranged around the first active region AC1 includes an upper surface at a lower level than the second element separation layer 60B arranged around the second active region AC2 and the third active region AC3. In addition, the channel semiconductor layer CH may be formed by an epitaxial process, while the edge portion ED1 of the first active region AC1 is in an exposed state. Accordingly, when the channel semiconductor layer CH is formed, an occurrence of a growth limit due to an interface of the first element separation layer 60A may be prevented, and the channel semiconductor layer CH may be substantially free of crystal defects such as dislocation and stacking faults. Thus, while the gate insulating layer GI3 of the third transistor TR3 is formed at a relatively large thickness, the channel semiconductor layer CH may have a good crystal quality. Therefore, the semiconductor device 100 including the periphery circuit transistor PTR may have an optimized performance.

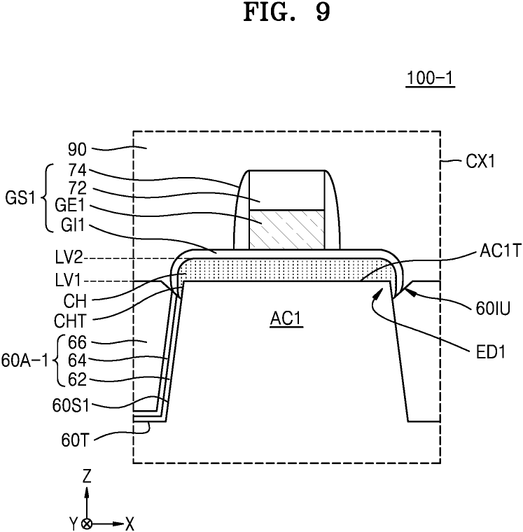

FIG. 9 is a cross-section view of a semiconductor device 100-1 according to an example embodiment of the inventive concept. In FIG. 9, the same reference numerals as those in FIGS. 1 through 8 may denote the same components.

Referring to FIG. 9, a first element separation layer 60A-1 may include a first liner layer 62, a second liner layer 64, and a filling insulation layer 66, which are sequentially arranged in the element separation trench 60T. For example, the first liner layer 62 and the second liner layer 64 may be conformally arranged on internal walls of the element separation trench 60T, and the filling insulation layer 66 may fill the inside of the element separation trench 60T on the second liner layer 64.

In example embodiments of the inventive concept, the first liner layer 62 may include silicon oxide. For example, the first liner layer 62 may include silicon oxide formed by using an atomic layer deposition (ALD) process, a chemical vapor deposition (CVD) process, a plasma enhanced CVD (PECVD) process, a low pressure CVD (LPCVD) process, etc. The second liner layer 64 may include silicon nitride. For example, the second liner layer 64 may include silicon nitride formed by using an ALD process, a CVD process, a PECVD process, an LPCVD process, etc. The filling insulation layer 66 may include silicon oxide such as tonen silazene (TOSZ), undoped silicate glass (USG), boro-phosphor silicate glass (BPSG), phosphor silicate glass (PSG), flowable oxide (FOX), plasma enhanced (PE) deposition of tetra-ethyl-ortho-silicate (TEOS) (PE_TEOS), and fluoride silicate glass (FSG).

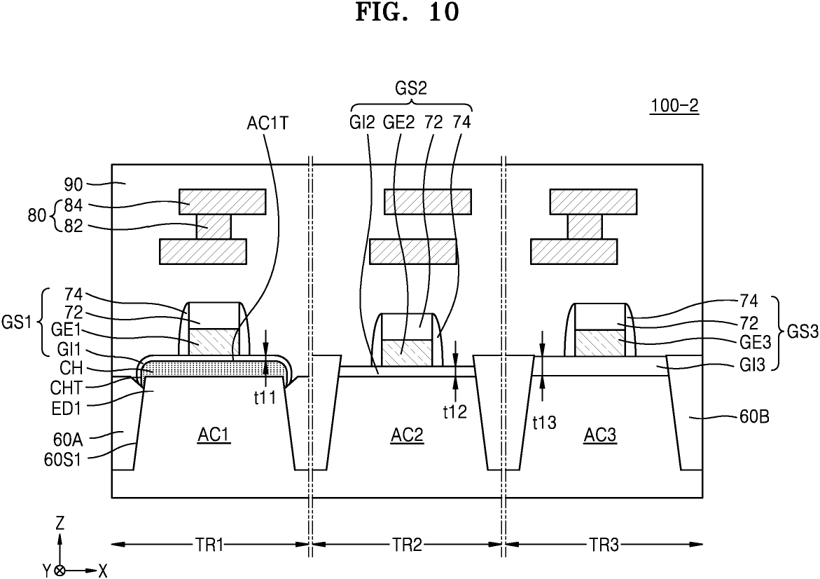

FIG. 10 is a cross-section view of a semiconductor device 100-2 according to an example embodiment of the inventive concept. In FIG. 10, the same reference numerals as those in FIGS. 1 through 9 may denote the same components.

Referring to FIG. 10, the first gate insulating layer GI1 may have a first thickness tl1 in the vertical direction (Z direction), the second gate insulating layer GI2 may have a second thickness t12 greater than the first thickness t11in the vertical direction (Z direction), and the third gate insulating layer GI3 may have a third thickness t13 greater than the second thickness t12 in the vertical direction (Z direction). As illustrated in FIG. 10, the upper surface of the second active region AC2 may be arranged on the same vertical level as the upper surface of the third active region AC3, and the upper surface of the third gate insulating layer GI3 may be arranged at a higher vertical level than the upper surface of the second gate insulating layer GI2. In addition, the level difference between the second gate insulating layer GI2 and the second element separation layer 60B may be greater than the level difference between the third gate insulating layer GI3 and the second element separation layer 60B.

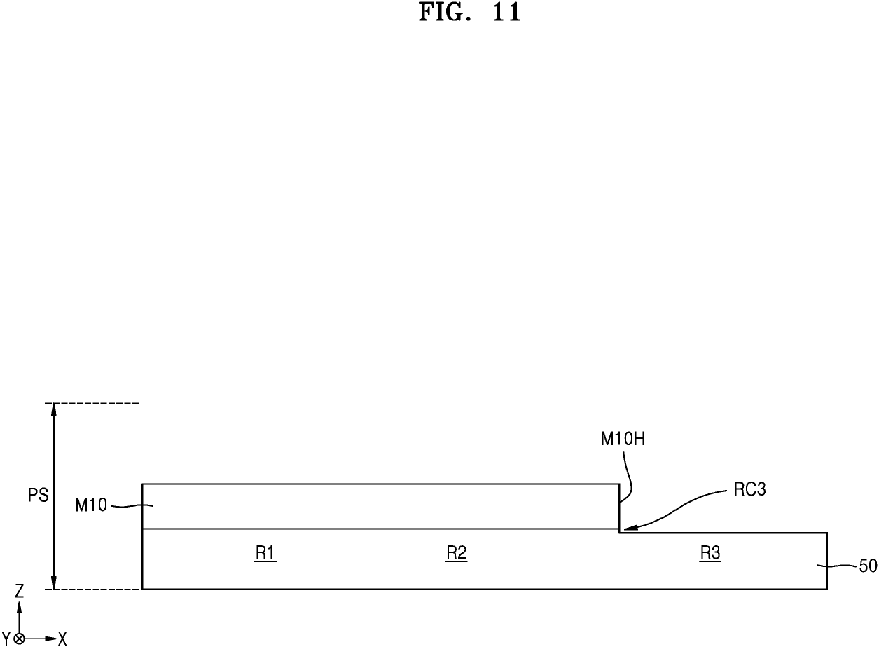

FIGS. 11 through 25 are cross-sectional views illustrating a manufacturing method of the semiconductor device 100, according to example embodiments of the inventive concept.

Referring to FIG. 11, the substrate 50 including a first region R1, a second region R2, and a third region R3 may be provided. The first region R1 may include a region where a first transistor TR1 (refer to FIG. 4) is to be formed, the second region R2 may include a region where the second transistor TR2 (refer to FIG. 4) is to be formed, and the third region R3 may include a region where the third transistor TR3 (refer to FIG. 4) is to be formed.

Thereafter, a mask pattern M10 including an opening M10H may be formed on the substrate 50. A recess region RC3 may be formed by removing the upper surface of the third region R3 of the substrate 50 by a certain thickness by using the mask pattern M10 as an etch mask.

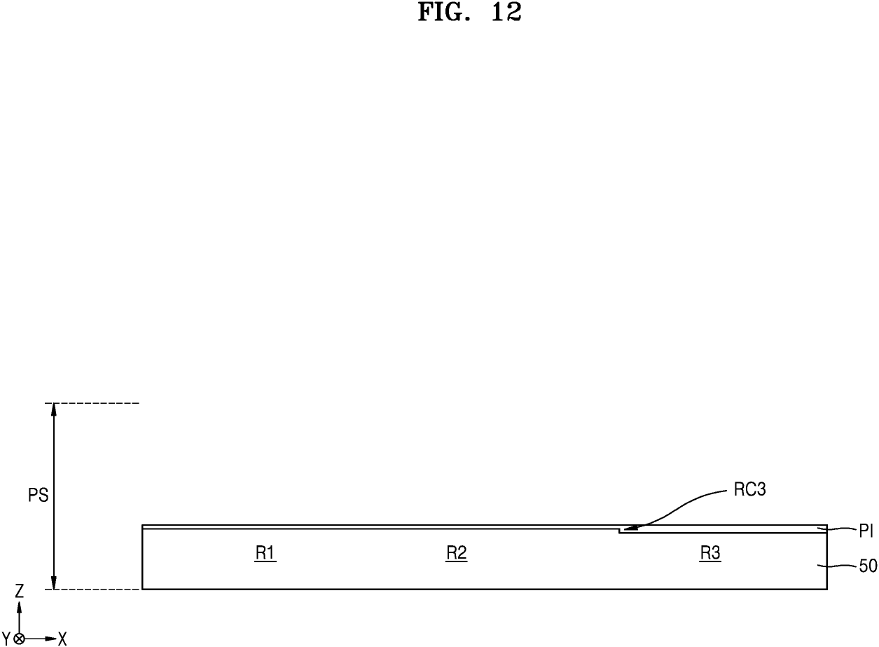

Referring to FIG. 12, a pad insulating layer PI may be formed on the substrate 50. The pad insulating layer PI may be arranged on all of the first region R1, the second region R2, and the third region R3. For example, the pad insulating layer PI may be formed to have a relatively small thickness (for example, the second thickness t12 (refer to FIG. 6)) on the first region R1 and the second region R2, and to have a relatively large thickness (for example, the third thickness t13 (refer to FIG. 6)) on the third region R3.

In example embodiments of the inventive concept, the pad insulating layer PI may include silicon oxide formed by using a thermal oxidation process, an ALD process, a CVD process, a PECVD process, an LPCVD process, etc. In other embodiments of the inventive concept, the pad insulating layer PI may be formed to have any one stacked structure of a silicon oxide layer formed by using a thermal oxidation process, a silicon nitride layer, a silicon oxynitride layer, an ONO layer, or a high-k layer having a higher dielectric constant than a silicon oxide layer, which are formed by using an ALD process, a CVD process, a PECVD process, an LPCVD process, etc.

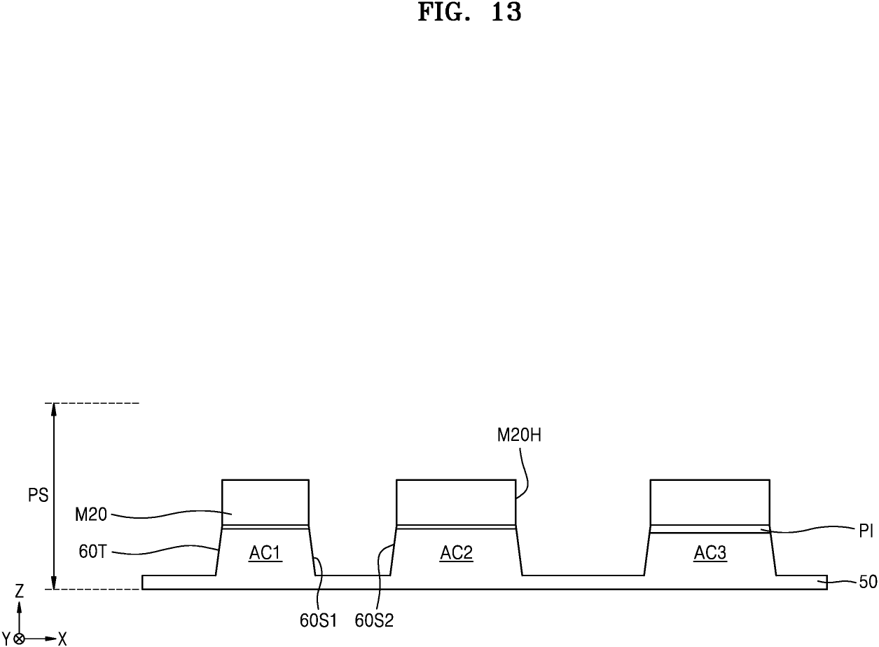

Referring to FIG. 13, a mask pattern M20 including an opening M20H may be formed on the pad insulating layer PI. Thereafter, the element separation trench 60T may be formed by removing portions of the pad insulating layer PI and the substrate 50 by using the mask pattern M20 as an etch mask.

By forming the element separation trench 60T, the first active region AC1 may be defined in the first region R1 of the substrate 50, the second active region AC2 may be defined in the second region R2 of the substrate 50, and the third active region AC3 may be defined in the third region R3 of the substrate 50,

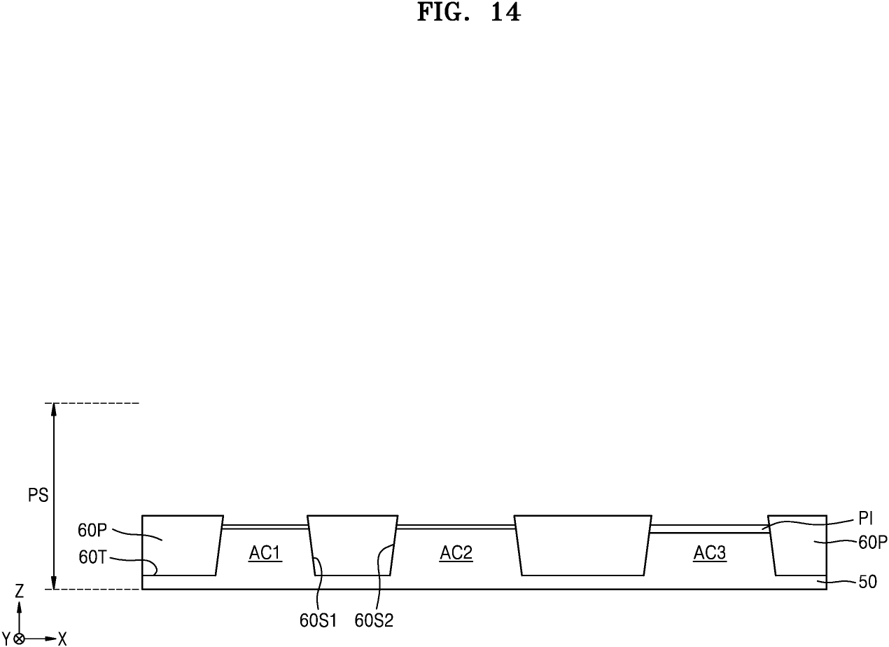

Referring to FIG. 14, an element separation layer 60P may be formed by forming an insulating layer in the element separation trench 60T and planarizing an upper portion of the insulating layer. In this case, the element separation layer 60P may be formed to have the upper surface arranged at a higher vertical level than the pad insulating layer PI.

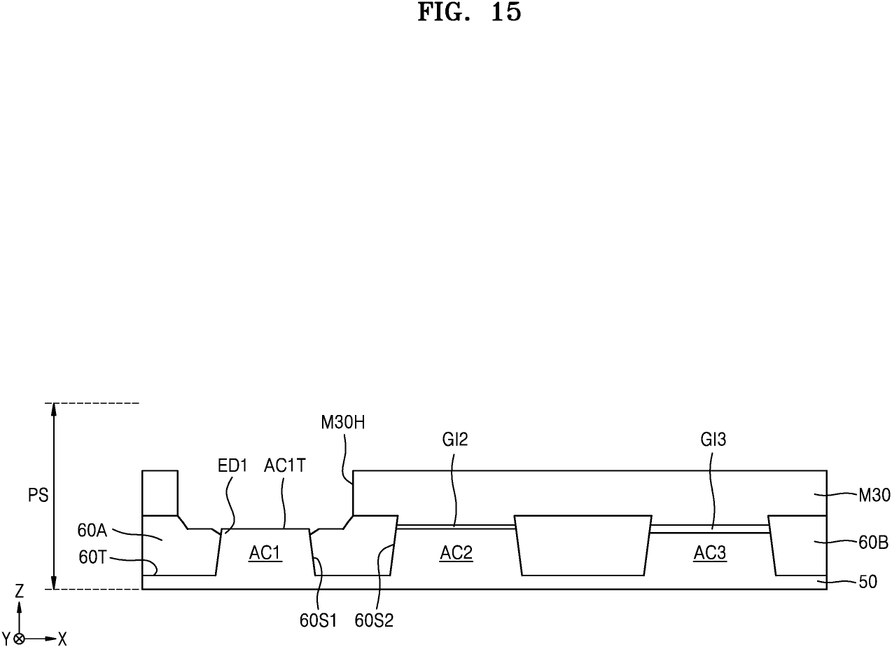

Referring to FIG. 15, a mask pattern M30 including an opening M30H may be formed on the pad insulating layer III and the element separation layer 60P (refer to FIG. 14). The opening M30H may be arranged to correspond to the first active region AC1 and a portion of the element separation layer 60P arranged around the first active region AC1.

Thereafter, the pad insulating layer PI exposed by the opening M30H may be removed, and the entire upper surface AC1T of the first active region AC1 may be exposed. In a process of removing the pad insulating layer PI, a portion of the element separation layer 60P arranged around the first active region AC1 may also be removed by a certain thickness. In other words, a recess may be formed in the element separation layer 60P arranged around the first active region AC1. Alternatively, after the pad insulating layer PI is removed, a recess process for removing an upper portion of the element separation layer 60P may be further performed.

In example embodiments of the inventive concept, the recess process may include a wet etching process or a dry etching process. The recess process may include an etching process using an etch selectivity with respect to the element separation layer 60P. In some example embodiments of the inventive concept, the element separation layer 60P may include the first liner layer 62, the second liner layer 64, and the filling insulation layer 66, and in this case, a process of etching the filling insulation layer 66, a process of etching the second liner layer 64, and a process of etching the first liner layer 62 may also be sequentially performed.

By using the recess process, the entire upper surface AC1T and the edge portion ED1 of the first active region AC1 may be exposed. In other words the edge portion ED1 of the first active region AC1 is not covered by the element separation layer 60P. The edge portion ED1 of the first active region AC1 may correspond to where the upper surface AC1T and sides of the first active region AC1 meet. In this case, a portion of the element separation layer 60P, in which a height thereof is lowered by applying the recess process to the upper portion thereof, (in other words, a portion of the element separation layer 60P around the first active region AC1), may be referred to as the first element separation layer 60A, and a portion of the element separation layer 60P, to which the recess process has not been applied, (in other words, a portion of the element separation layer 60P around the second active region AC2 and the third active region AC3), may be referred to as the second element separation layer 60B. The upper surface of the first element separation layer 60A arranged around the first active region AC1 may be arranged at a lower level than the upper surface of the first active region AC1. In other words, the upper surface of the first element separation layer 60A that contacts the first active region AC1 may be at a lower level than the upper surface of the first active region AC1.

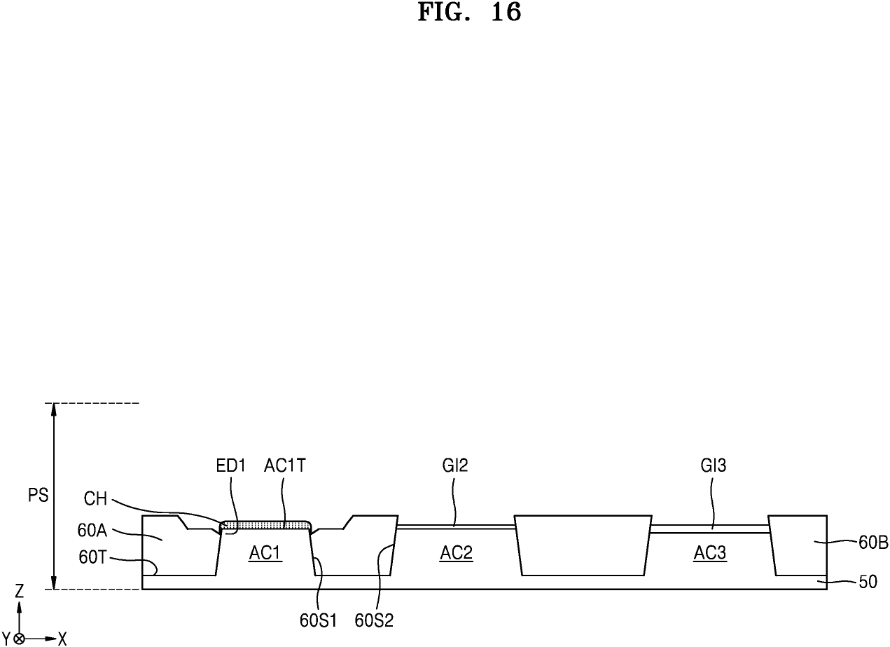

Referring to FIG. 16, the channel semiconductor layer CH may be formed on the entire upper surface AC1T of the exposed first active region AC1. In example embodiments of the inventive concept, the channel semiconductor layer CH may cover the edge portion ED1 of the exposed first active region AC1, and extend downwardly. For example, the channel semiconductor layer CH may be disposed in a space adjacent to the edge portion ED1.

In example embodiments of the inventive concept, the channel semiconductor layer CH may be formed by using an epitaxial growth process by using the upper surface of the substrate 50 as a seed material. For example, the substrate 50 may include silicon, and the channel semiconductor layer CH may include silicon germanium. Particularly, because, in a growth process of the channel semiconductor layer CH, the first element separation layer 60A is arranged at a lower level than the upper surface of the first active region AC1, and does not cover the edge portion ED1 of the first active region AC1, the channel semiconductor layer CH may be substantially free of crystal defects such as dislocation and stacking faults.

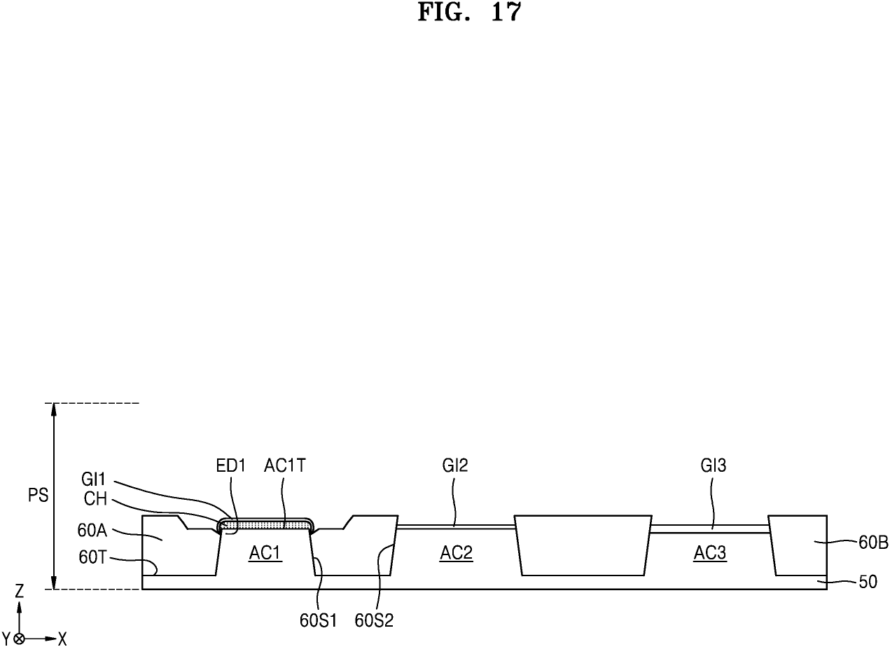

Referring to FIG. 17, a portion of the pad insulating layer PI on the second active region AC2 may be removed.

The first gate insulating layer GI1 may be formed on the channel semiconductor layer CH, and the second gate insulating layer GI2 may be formed on the second active region AC2.

In example embodiments of the inventive concept, the first gate insulating layer GI1 and the second gate insulating layer GI2 may be formed by using at least one selected from a silicon oxide layer, a silicon oxynitride layer, an ONO layer, or a high-k layer having a higher dielectric constant than a silicon oxide layer, by using an ALD process, a CVD process, a PECVD process, an LPCVD process, etc.

In some embodiments of the inventive concept, the second gate insulating layer GI2 may be firstly formed, and thereafter, the first gate insulating layer GI1 may be formed. In other embodiments of the inventive concept, the second gate insulating layer GI2 and the first gate insulating layer GI1 may be simultaneously formed.

A portion of the pad insulating layer PI on the third active region AC3 may be referred to as the third gate insulating layer GI3. In some embodiments of the inventive concept, in a process of forming the first gate insulating layer GI1 and the second gate insulating layer GI2, an additional insulating layer may be further formed on the pad insulating layer PI on the third active region AC3.

In example embodiments of the inventive concept, the first gate insulating layer GI1 may be formed to have a thickness less than the second gate insulating layer GI2 and the third gate insulating layer GI3 (for example, the first thickness t11 (refer to FIG. 6)).

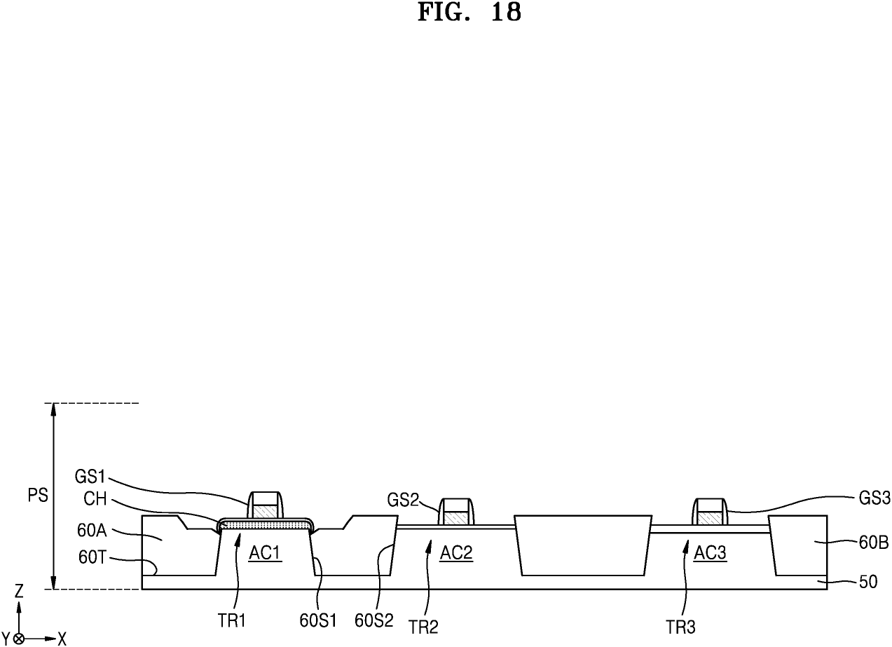

Referring to FIG. 18, a conductive layer and a capping insulating layer may be formed on the first through third gate insulating layers GI1, GI2, and GI3, and by patterning the capping insulating layer and the conductive layer, the first through third gate electrodes GE1, GE2, and GE3 (refer to FIG. 6) and the gate capping layer 72 may be formed, respectively. Thereafter, an insulating layer covering the first through third gate electrodes GE1, GE2, and GE3 and the gate capping layer 72 may be formed, and by performing an anisotropic etching process on the insulating layer, the gate spacer 74 may be formed. In this manner, the first gate structure GS1 may be formed on the first active region AC1, the second gate structure GS2 may be formed on the second active region AC2, and the third gate structure GS3 may be formed on the third active region AC3.

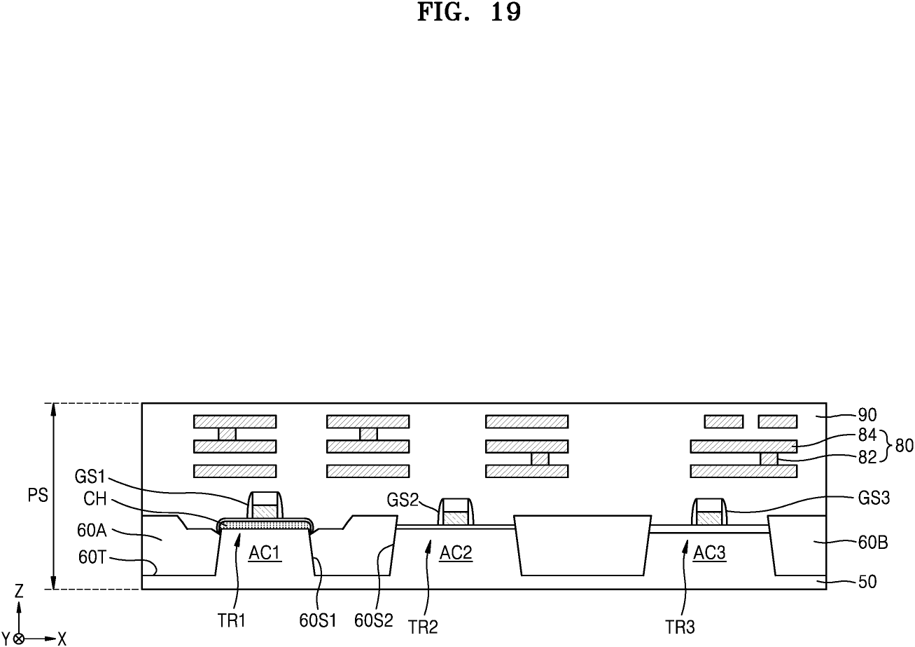

Referring to FIG. 19, the periphery circuit wiring structure 80 and the interlayer insulating layer 90, which are electrically connected to the first through third gate structures GS1, GS2, and GS3 and the first through third active regions AC1, AC2, and AC3, may be formed.

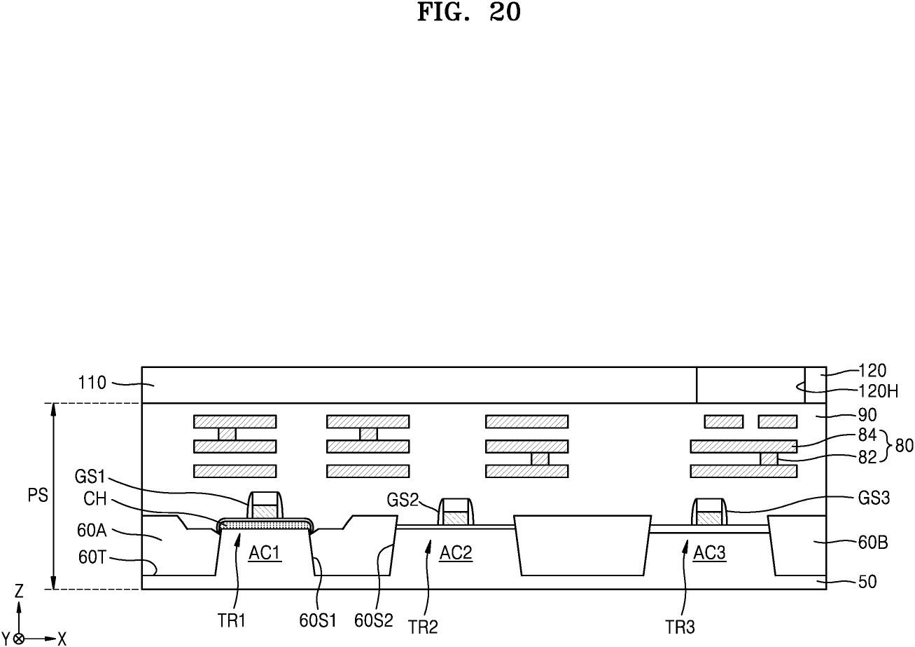

Referring to FIG. 20, the common source plate 110 may be formed on the interlayer insulating layer 90. In some example embodiments of the inventive concept, the common source plate 110 may be formed by using a semiconductor doped with n-type impurities.

Thereafter, a mask pattern may be formed on the common source plate 110, and by removing a portion of the common source plate 110 by using the mask pattern as an etch mask, the opening 120H may be formed. Thereafter, an insulating layer filling an opening 120H may be formed on the common source plate 110, and by planarizing an upper portion of the insulating layer until the upper surface of the common source plate 110 is exposed, the insulation plug 120 may be formed.

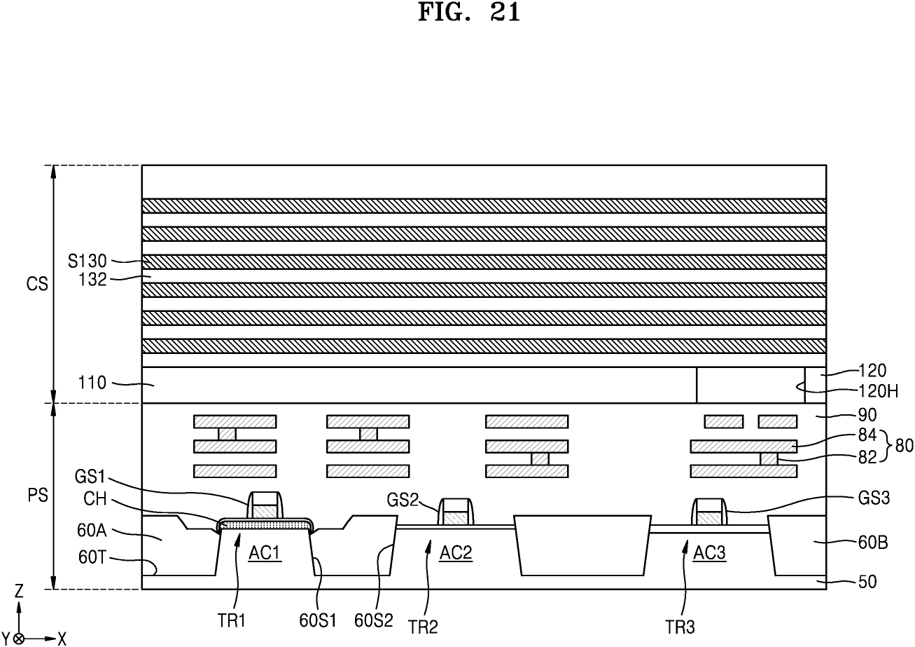

Referring to FIG. 21, the plurality of mold insulating layers 132 and a plurality of sacrificial layers S130 may be alternately formed on the common source plate 110. In example embodiments of the inventive concept, the plurality of mold insulating layers 132 may include an insulating material such as silicon oxide and silicon oxynitride, and the plurality of sacrificial layers S130 may also include silicon nitride, silicon oxynitride, doped polysilicon, etc.

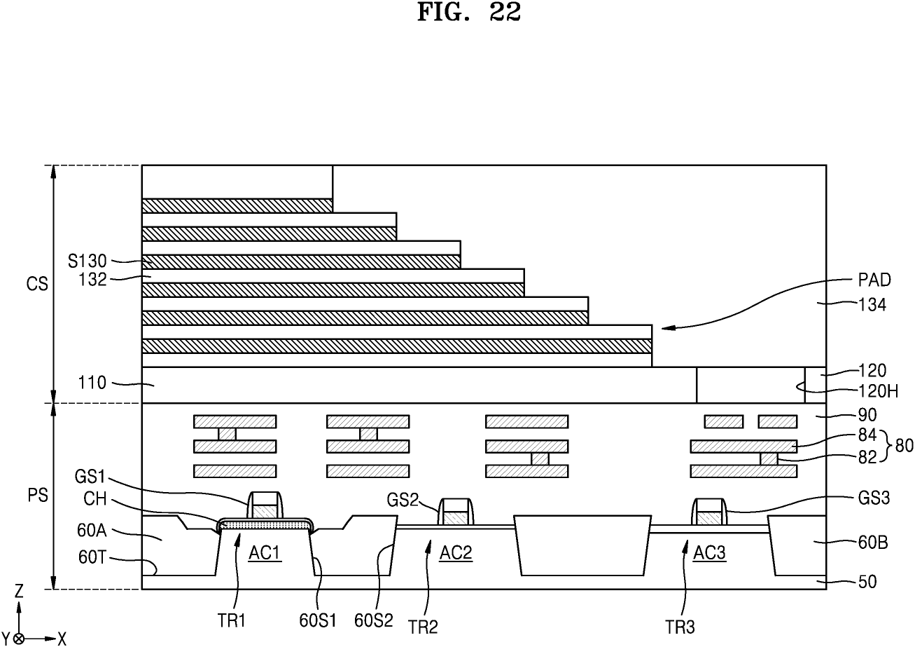

Referring to FIG. 22, by sequentially patterning the plurality of mold insulating layers 132 and the plurality of sacrificial layers S130, the pad structure PAD may be formed. In example embodiments of the inventive concept, the pad structure PAD may be formed to have a stair shape, which has differences of the upper surface levels in the first horizontal direction (X direction) (refer to FIG. 4).

Thereafter, the cover insulating layer 134 covering the pad structure PAD may be formed. The cover insulating layer 134 may include an insulating material such as silicon oxide and silicon oxynitride.

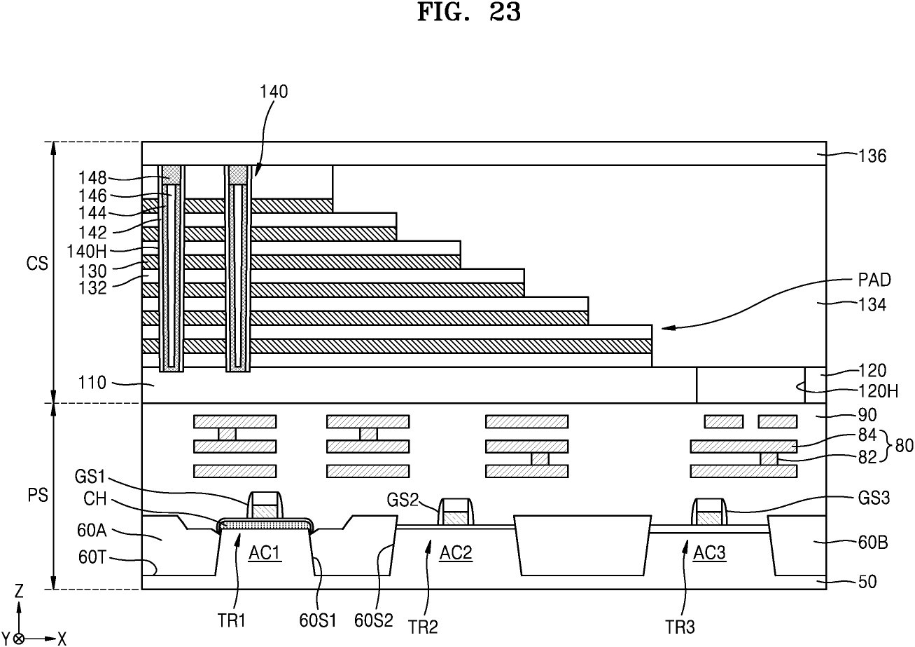

Referring to FIG. 23, a mask pattern may be formed on the mold insulating layer 132 at the uppermost portion and the cover insulating layer 134, and by patterning the plurality of mold insulating layers 132 and the plurality of sacrificial layers S 130 by using the mask pattern as an etch mask, the channel hole 140H may be formed.

Thereafter, the channel structure 140 including the gate insulating layer 142, the channel layer 144, the filled insulating layer 146, and the conductive plug 148 may be formed on the internal wall of the channel hole 140H.

In addition, in a process of forming the channel structure 140, a dummy channel structure penetrating another pad structure may be formed.

Thereafter, the upper insulating layer 136 covering the mold insulating layer 132 at the uppermost portion, the cover insulating layer 134, and the channel structure 140 may be formed.

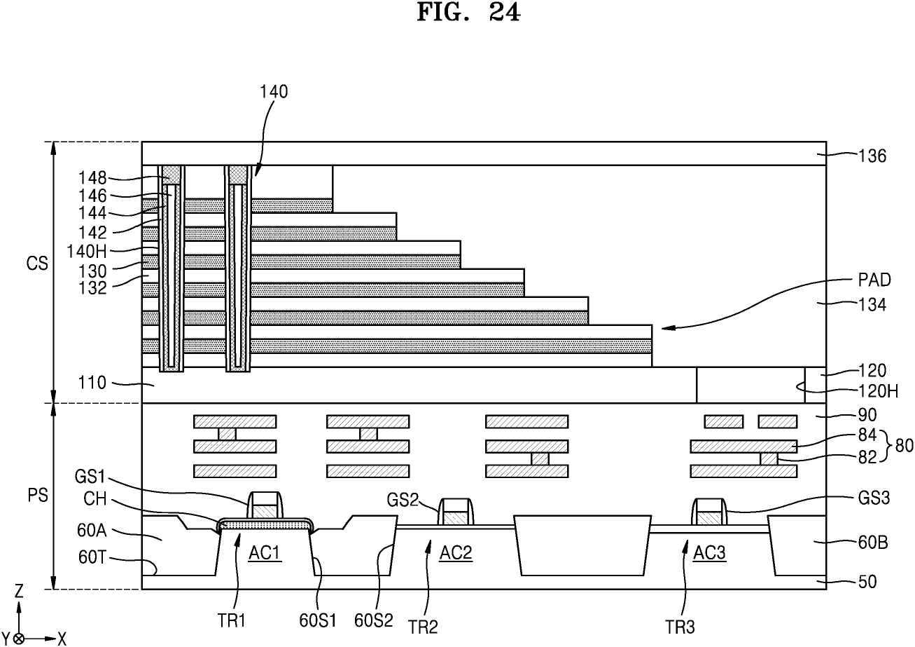

Referring to FIG. 24, a mask pattern may be formed on the upper insulating layer 136, and by removing portions of the plurality of mold insulating layers 132 and the plurality of sacrificial layers S130 by using the mask pattern as an etch mask, a gate stack separation opening may be formed. The plurality of sacrificial layers S130 exposed on the internal wall of the gate stack separation opening may be removed. In example embodiments of the inventive concept, a removing process of the plurality of sacrificial layers S130 may include a wet etching process using a phosphoric acid solution as an etchant. As the plurality of sacrificial layers S130 are removed, a portion of sidewalls of the channel structure 140 may be exposed.

Thereafter, the plurality of gate electrodes 130 may be formed in a space, where the plurality of sacrificial layers S130 has been removed. Thereafter, the inside of the gate stack separation opening may be filled with an insulating material.

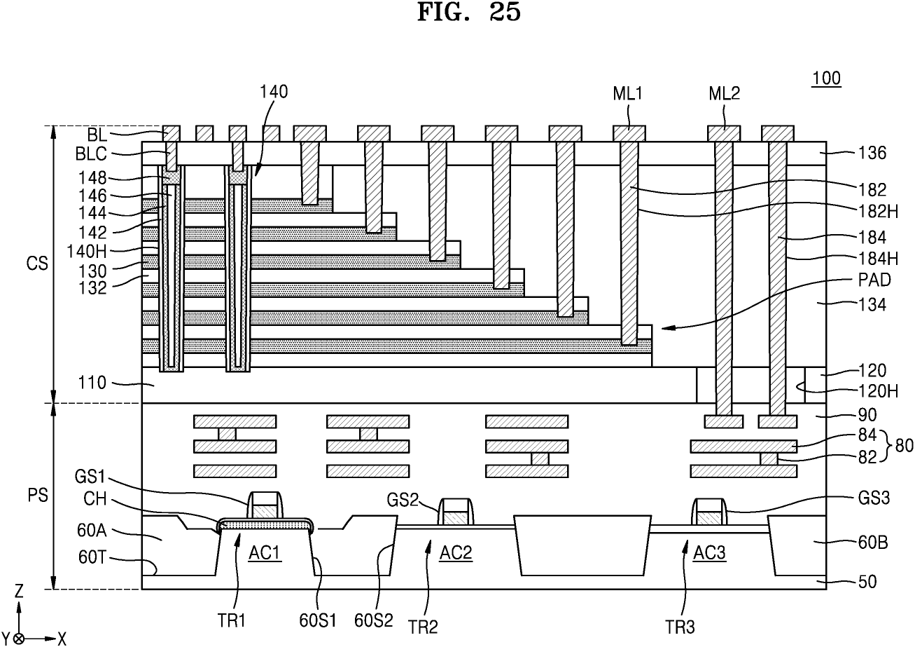

Referring to FIG. 25, the bit line contact BLC penetrating the upper insulating layer 136 may be formed. The cell contact hole 182H penetrating the upper insulating layer 136 and the cover insulating layer 134 may be formed, and the cell contact plug 182 may be formed in the cell contact hole 182H. In addition, the conductive through via 184 may be formed inside the through hole 184H penetrating the upper insulating layer 136, the cover insulating layer 134, and the insulation plug 120.

Thereafter, the bit line BL connected to the bit line contact BLC may be formed on the upper insulating layer 136, and the first wiring line ML1 connected to the cell contact plug 182 and the second wiring line ML2 connected to the conductive through via 184 may be formed.

By using the processes described above, the semiconductor device 100 may be completed.

In general, the periphery circuit structure PS may include various periphery circuit transistors PTR providing power and signals to the cell array structure CS for driving the cell array structure CS. Particularly, because it is necessary to form a relatively thick gate insulating layer for forming a transistor included in a high voltage region (for example, a transistor such as the third transistor TR3), an upper surface of an element separation layer may be formed at a higher level than an upper surface of the gate insulating layer to prevent a thickness reduction of the gate insulating layer. However, in a process of forming a channel semiconductor layer for a transistor included in a low voltage region, there may be a growth limit due to an interface of a high element separation layer, and thus, crystal defects at an edge portion of an active region may occur.

However, according to example embodiments of the inventive concept described above, a recess process may be performed so that the first element separation layer 60A arranged around the first active region AC1 includes the upper surface at a lower level than the second element separation layer 60B arranged around the second active region AC2 and the third active region AC3. In addition, the channel semiconductor layer CH may be formed by an epitaxial process, with the edge portion ED1 of the first active region AC1 in an exposed state. Accordingly, when the channel semiconductor layer CH is formed, an occurrence of a growth limit due to an interface of the first element separation layer 60A may be prevented, and the channel semiconductor layer CH may be substantially free of crystal defects such as dislocation or stacking faults. Thus, while the third gate insulating layer GI3 of the third transistor TR3 is formed at a relatively large thickness, the channel semiconductor layer CH may have a good crystal quality. Therefore, the semiconductor device 100 including the periphery circuit transistor PTR may have an optimized performance.

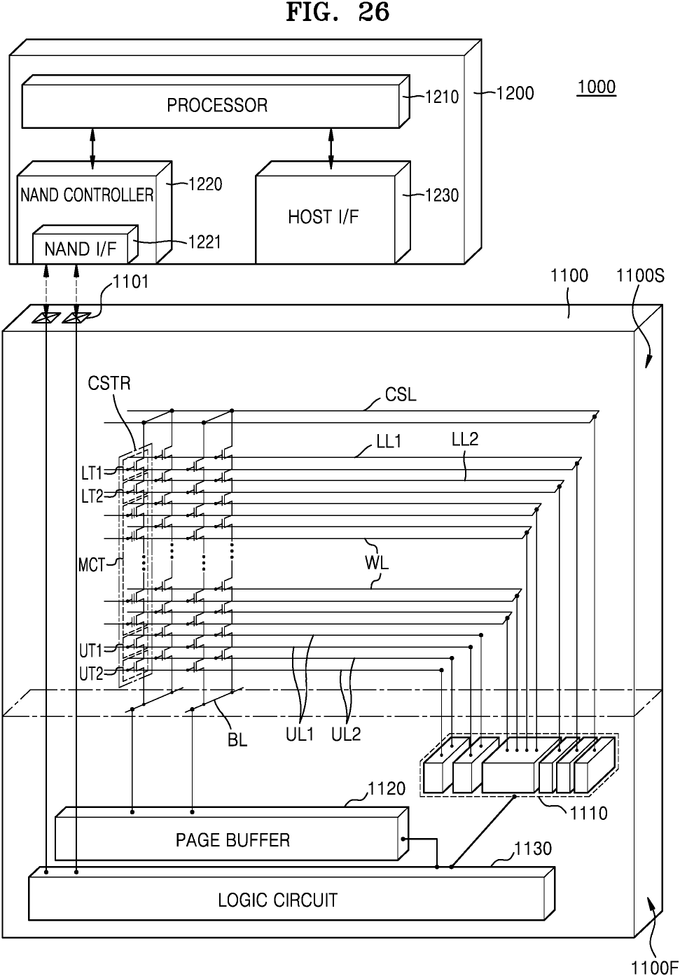

FIG. 26 is a schematic diagram of a data storage system 1000 including a semiconductor device 1100, according to an example embodiment of the inventive concept.

Referring to FIG. 26, the data storage system 1000 may include one or more semiconductor devices 1100, and a memory controller 1200 electrically connected to the semiconductor device 1100. The data storage system 1000 may, for example, include a solid state drive (SSD) device, universal serial bus (USB), a computing system, a medical device, or a communication device, which includes at least one semiconductor device 1100.

The semiconductor device 1100 may include a non-volatile semiconductor device, and for example, the semiconductor device 1100 may include an NAND flash semiconductor device including one of the semiconductor devices 10, 100, 100-1, and 100-2 described with reference to FIGS. 1 through 10. The semiconductor device 1100 may include a first structure 1100F and a second structure 1100S on the first structure 1100F. The first structure 1100F may include a periphery circuit structure including a row decoder 1110, a page buffer 1120, and a logic circuit 1130.

The second structure 1100S may have a memory cell structure including the bit line BL, the common source line CSL, the plurality of word lines WL, a first gate upper line UL1 and a second gate upper line UL2, a first ground selection line LL1 and a second ground selection line LL2, and a plurality of memory cell strings CSTR between the bit line BL and the common source line CSL.

In the second structure 1100S, each of the plurality of memory cell strings CSTR may include ground selection transistors LT1 and LT2 adjacent to the common source line CSL, and string selection transistors UT1 and UT2 adjacent to the bit line BL, and a plurality of memory cell transistors MCT arranged between the ground selection transistors LT1 and LT2 and the string selection transistors UT1 and UT2. The number of the ground selection transistors LT1 and LT2 and the number of the string selection transistors UT1 and UT2 may be variously modified according to embodiments of the inventive concept.

In example embodiments of the inventive concept, the plurality of ground selection lines LL1 and LL2 may be connected to gate electrodes of the ground selection transistors LT1 and LT2, respectively. The word line WL, may be connected to a gate electrode of the memory cell transistor MCT. The plurality of string selection lines UL1 and UL2 may be connected to gate electrodes of the string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The semiconductor device 1100 may communicate with the memory controller 1200 via an I/O pad 1101 electrically connected to the logic circuit 1130.

The memory controller 1200 may include a processor 1210, an NAND controller 1220, and a host interface (I/F) 1230. In some embodiments of the inventive concept, the data storage system 1000 may include a plurality of semiconductor devices 1100, and in this case, the memory controller 1200 may control the plurality of semiconductor devices 1100.

The processor 1210 may control the overall operation of the data storage system 1000 including the memory controller 1200. The processor 1210 may operate according to certain firmware, and may access the semiconductor device 1100 by controlling the NAND controller 1220. The NAND controller 1220 may include an NAND I/F 1221, which processes communication with the semiconductor device 1100, Via the NAND I/F 1221, a control command for controlling the semiconductor device 1100, data to be written to the plurality of memory cell transistors MCT of the semiconductor device 1100, data to be read from the plurality of memory cell transistors MCT of the semiconductor device 1100, or the like may be transmitted. The host I/F 1230 may provide a communication function between the data storage system 1000 and an external host. When a control command is received from the external host via the host I/F 1230, the processor 1210 may control the semiconductor device 1100 in response to the control command.

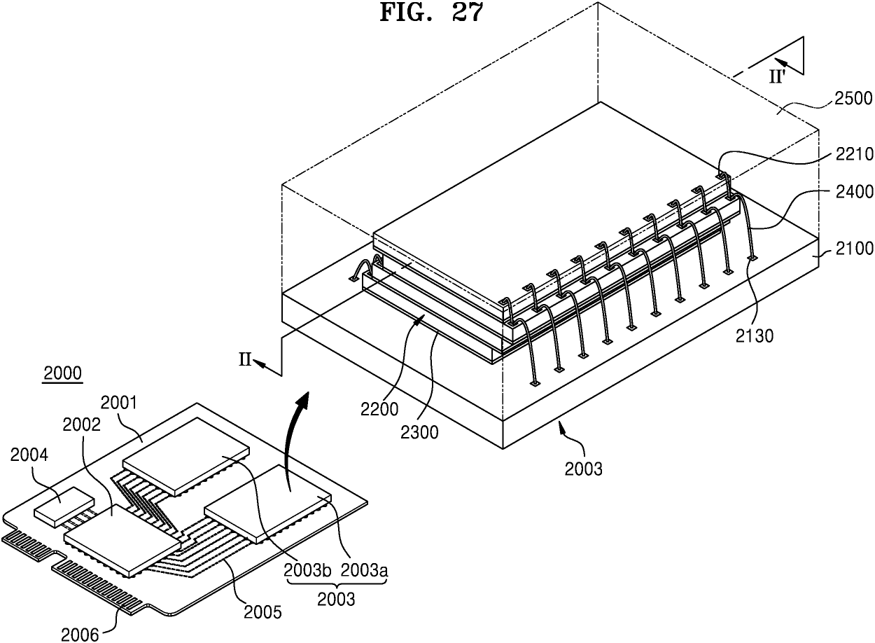

FIG. 27 is a perspective view of a data storage system 2000 including a semiconductor device, according to an example embodiment of the inventive concept.

Referring to FIG. 27, the data storage system 2000 may include a main substrate 2001, a controller 2002 mounted on the main substrate 2001, one or more semiconductor packages 2003, and a dynamic random access memory (DRAM) 2004. The semiconductor package 2003 and the DRAM 2004 may be connected to the controller 2002 via a plurality of wiring patterns 2005 formed on the main substrate 2001.

The main substrate 2001 may include a connector 2006 including a plurality of pins coupled with the external host. The number and arrangement of the plurality of pins of the connector 2006 may vary according to a communication interface between the data storage system 2000 and the external host. In example embodiments of the inventive concept, the data storage system 2000 may communicate with the external host according to any one of interfaces such as USB, peripheral component interconnect (PCI) express (PCI-E), serial advanced technology attachment (SATA), and M-Phy for a universal flash storage (UFS). In example embodiments of the inventive concept, the data storage system 2000 may operate by power supplied by the external host via the connector 2006. The data storage system 2000 may also further include a power management integrated circuit (PMIC), which distributes power supplied by the external host to the memory controller 2002 and the semiconductor package 2003.

The memory controller 2002 may write data to the semiconductor package 2003, or read data from the semiconductor package 2003, and may improve an operation speed of the data storage system 2000.

The DRAM 2004 may include a buffer memory for reducing a speed difference between the semiconductor package 2003, which is a data storage space, and the external host. The DRAM 2004 included in the data storage system 2000 may also operate as a cache memory, and may also provide a space for temporarily storing data in a control operation on the semiconductor package 2003. When the DRAM 2004 is included in the data storage system 2000, the memory controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b, which are apart from each other. Each of the first and second semiconductor packages 2003a and 2003b may include a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 arranged on a lower surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 on the package substrate 2100.

The package substrate 2100 may include a printed circuit board including a plurality of package upper pads 2130. Each of the plurality of semiconductor chips 2200 may include an I/O pad 2210. The I/O pad 2210 may correspond to the I/O pad 1101 in FIG. 26. Each of the plurality of semiconductor chips 2200 may include at least one of the semiconductor devices 10, 100, 100-1, and 100-2 described with reference to FIGS. 1 through 10.

In example embodiments of the inventive concept, the connection structure 2400 may include a bonding wire electrically connecting the I/O pad 2210 to the package upper pad 2130. Accordingly, in the first and second semiconductor packages 2003a and 2003b, the plurality of semiconductor chips 2200 may be electrically connected to each other by a bonding wire method, and may be electrically connected to the package upper pad 2130 of the package substrate 2100. According to example embodiments of the inventive concept, in the first and second semiconductor packages 2003a and 2003b, the plurality of semiconductor chips 2200 may also be electrically connected to each other via a connection structure including through silicon vias TSV, instead of the connection structure 2400 of a bonding wire method.

In example embodiments of the inventive concept, the memory controller 2002 and the plurality of semiconductor chips 2200 may also be included in one package. In an example embodiment of the inventive concept, the memory controller 2002 and the plurality of semiconductor chips 2200 may be mounted on an interposer substrate discretely different from the main substrate 2001, and the memory controller 2002 and the plurality of semiconductor chips 2200 may also be connected to each other via wiring formed on the interposer substrate.

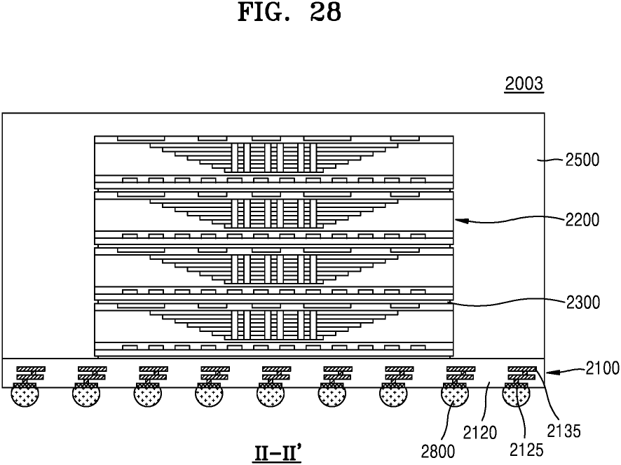

FIG. 28 is a schematic cross-sectional view of a semiconductor package 2003 according to an example embodiment of the inventive concept. FIG. 28 is a cross-sectional view taken along line II-II′ in FIG. 27.

Referring to FIG. 28, in the semiconductor package 2003, the package substrate 2100 may include a printed circuit board. The package substrate 2100 may include a package substrate body unit 2120, the plurality of package upper pads 2130 (refer to FIG. 27) arranged on an upper surface of the package substrate body unit 2120, a plurality of lower pads 2125 arranged on a lower surface of the package substrate body unit 2120 or exposed via the lower surface thereof, and a plurality of internal wiring 2135 electrically connecting the plurality of package upper pads 2130 (refer to FIG. 27) to the plurality of lower pads 2125 inside the package substrate body unit 2120. As illustrated in FIG. 27, the plurality of package upper pads 2130 may be electrically connected to a plurality of connection structures 2400. As illustrated in FIG. 28, the plurality of lower pads 2125 may be connected to the plurality of wiring patterns 2005 on the main substrate 2001 of the data storage system 2000 illustrated in FIG. 27 via a plurality of conductive bumps 2800. Each of the plurality of semiconductor chips 2200 may include at least one of the semiconductor devices 10, 100, 100-1, and 100-2 described with reference to FIGS. 1 through 10.

While the inventive concept has been particularly shown and described with reference to embodiments thereof, it will be understood that various changes in form and details may be made thereto without departing from the spirit and scope of the inventive concept as set forth in the following claims.

What is claimed is:

1. A semiconductor device, comprising:
a periphery circuit structure arranged on a substrate; and
a memory cell array arranged on the periphery circuit structure, and comprising a plurality of memory cells arranged in a first direction substantially perpendicular to an upper surface of the substrate,
wherein the periphery circuit structure comprises:
a first element separation layer arranged on the substrate and defining a first active region;
a channel semiconductor layer arranged on the first active region and at a higher level than an upper surface of the first element separation layer;
a first gate structure arranged on the channel semiconductor layer;
a second element separation layer arranged on the substrate, defining a second active region and a third active region, and comprising an upper surface at a higher level than the upper surface of the first element separation layer,
a second gate structure arranged on the second active region; and
a third gate structure arranged on the third active region.

2. The semiconductor device of claim 1, wherein the substrate comprises silicon, and
the channel semiconductor layer comprises silicon germanium.

3. The semiconductor device of claim 1, wherein an edge portion of the first active region is not covered by the first element separation layer, and
the channel semiconductor layer covers an upper surface and the edge portion of the first active region.

4. The semiconductor device of claim 3, wherein the channel semiconductor layer is substantially free of crystal defects.

5. The semiconductor device of claim 1, wherein the first gate structure comprises:
a first gate insulating layer arranged on the channel semiconductor layer and having a first thickness in the first direction; and
a first gate electrode arranged on the first gate insulating layer,
wherein the second gate structure comprises:
a second gate insulating layer arranged on the second active region and having a second thickness greater than the first thickness in the first direction; and
a second gate electrode arranged on the second gate insulating layer, and
wherein the third gate structure comprises:
a third gate insulating layer arranged on the third active region and having a third thickness greater than the second thickness in the first direction; and
a third gate electrode on the third gate insulating layer.

6. The semiconductor device of claim 5, wherein the upper surface of the first element separation layer is at a lower level than an upper surface of the first gate insulating layer,
an upper surface of the second element separation layer is at a higher level than an upper surface of the second gate insulating layer, and
the upper surface of the second element separation layer is at a higher level than an upper surface of the third gate insulating layer.

7. The semiconductor device of claim 5, wherein the channel semiconductor layer comprises a tail portion extending downwardly on an edge portion of the first active region, and
the first gate insulating layer covers the tail portion of the channel semiconductor layer on the edge portion of the first active region.

8. The semiconductor device of claim 7, wherein the first element separation layer comprises a first side contacting the first active region and a second side opposite to the first side, and
an upper surface level of the first element separation layer on the first side is lower than an upper surface level of the first element separation layer on the second side.

9. The semiconductor device of claim 1, wherein the first active region, the channel semiconductor layer, and the first gate structure constitute a p-channel metal-oxide-semiconductor (PMOS) transistor having a first threshold voltage,
the second active region and the second gate structure constitute an n-channel metal-oxide-semiconductor (NMOS) transistor or a PMOS transistor having a second threshold voltage different from the first threshold voltage, and
the third active region and the third gate structure constitute an NMOS transistor or a PMOS transistor having a third threshold voltage different from the second threshold voltage.

10. The semiconductor device of claim 1, wherein the first element separation layer comprises a first liner layer arranged inside an element separation trench arranged inside the substrate,
a second liner layer on the first liner layer, and
a filling insulation layer filling an inside of the element separation trench on the second liner layer.

11. The semiconductor device of claim 1, wherein the memory cell array comprises:
a common source plate arranged on the periphery circuit structure;
a plurality of gate electrodes arranged apart from each other on the common source plate in the first direction; and
a channel structure configured to penetrate the plurality of gate electrodes from an upper surface of the common source plate and extending in the first direction, and
wherein each of the plurality of memory cells comprises one gate electrode among the plurality of gate electrodes and a portion of the channel structure arranged adjacent to the one gate electrode.

12. A semiconductor device, comprising:
a first element separation layer arranged on a substrate and defining a first active region;
a second element separation layer arranged on the substrate, defining a second active region and a third active region, and comprising an upper surface at a higher level than an upper surface of the first element separation layer;
a first transistor arranged on the substrate and having a first threshold voltage, the first transistor comprising:
the first active region;
a channel semiconductor layer arranged on the first active region and at a higher level than the upper surface of the first element separation layer; and
a first gate structure arranged on the channel semiconductor layer;
a second transistor arranged on the substrate and having a second threshold voltage, the second transistor comprising:
the second active region; and
a second gate structure arranged on the second active region; and
a third transistor arranged on the substrate and having a third threshold voltage, the third transistor comprising:
the third active region; and
a third gate structure arranged on the third active region.

13. The semiconductor device of claim 12, wherein the first transistor comprises a p-channel metal-oxide-semiconductor (PMOS) transistor,
the second transistor comprises a PMOS transistor or an n-channel metal-oxide-semiconductor (NMOS) transistor, and
the third transistor comprises a PMOS transistor or an NMOS transistor.

14. The semiconductor device of claim 12, wherein an edge portion of the first active region is not covered by the first element separation layer, and
the channel semiconductor layer covers an upper surface and the edge portion of the first active region.

15. The semiconductor device of claim 14, wherein the first gate structure comprises:
a first gate insulating layer arranged on the channel semiconductor layer and having a first thickness in a first direction substantially perpendicular to an upper surface of the substrate; and
a first gate electrode arranged on the first gate insulating layer,
wherein the second gate structure comprises:
a second gate insulating layer arranged on the second active region and having a second thickness greater than the first thickness in the first direction; and
a second gate electrode arranged on the second gate insulating layer, and
wherein the third gate structure comprises:
a third gate insulating layer arranged on the third active region and having a third thickness greater than the second thickness in the first direction; and
a third gate electrode on the third gate insulating layer.

16. The semiconductor device of claim 15, wherein the upper surface of the first element separation layer is at a lower level than an upper surface of the first gate insulating layer,
an upper surface of the second element separation layer is at a higher level than an upper surface of the second gate insulating layer, and
the upper surface of the second element separation layer is at a higher level than an upper surface of the third gate insulating layer.

17. The semiconductor device of claim 15, wherein the channel semiconductor layer comprises a tail portion extending downwardly on the edge portion of the first active region, and
the first gate insulating layer covers the tail portion of the channel semiconductor layer on the edge portion of the first active region.

18. The semiconductor device of claim 17, wherein the first element separation layer comprises a first side contacting the first active region and a second side opposite to the first side, and
an upper surface of the first element separation layer on the first side is arranged at a lower level than an upper surface of the first element separation layer on the second side.

19. The semiconductor device of claim 12, wherein the first element separation layer comprises:
a first liner layer arranged inside an element separation trench arranged inside the substrate,
a second liner layer on the first liner layer; and
a filling insulation layer filling an inside of the element separation trench on the second liner layer.

20. An electronic system, comprising:
a first substrate;
a semiconductor device on the first substrate; and
a controller electrically connected to the semiconductor device,
wherein the semiconductor device comprises:
a periphery circuit structure arranged on a second substrate; and
a memory cell array arranged on the periphery circuit structure, and comprising a plurality of memory cells arranged in a first direction substantially perpendicular to an upper surface of the second substrate,
wherein the peripheral circuit structure comprises:
a first element separation layer arranged on the second substrate and defining a first active region; and
a second element separation layer arranged on the second substrate, defining a second active region and a third active region, and comprising an upper surface at a higher level than an upper surface of the first element separation layer;
a first transistor arranged on the second substrate and having a first threshold voltage, the first transistor comprising:
the first active region;
a channel semiconductor layer arranged on the first active region and at a higher level than the upper surface of the first element separation layer, and comprising silicon germanium; and
a first gate structure arranged on the channel semiconductor layer;
a second transistor arranged on the second substrate and having a second threshold voltage, the second transistor comprising:
the second active region; and
a second gate structure arranged on the second active region; and
a third transistor arranged on the second substrate and having a third threshold voltage, the third transistor comprising:
the third active region, and
a third gate structure arranged on the third active region.
